(19) United States
(12) Patent Application Publication
(10) Pub. No.: US 2025/0366193 A1
(43) Pub. Date: Nov. 27, 2025

(54) ELECTRONIC DEVICE HAVING VERTICALLY STACKED TRANSISTORS OVER SUBSRATE

(71) Applicant: Taiwan Semiconductor Manufacturing Company, Ltd., Hsinchu (TW)

(72) Inventors: Kuo-Chang Chiang, Hsinchu City (TW); Chih-Yu Chang, New Taipei City (TW); Yu-Chuan Shih, Hsinchu City (TW); Yan-Yi Chen, Taipei City (TW); Kuan-Chi Wang, Hsinchu (TW)

(21) Appl. No.: 18/923,782

(22) Filed: Oct. 23, 2024

Related U.S. Application Data
(60) Provisional application No. 63/651,420, filed on May 24, 2024.

(51) Int. Cl. H01L 27/092; H01L 21/8256; H01L 29/66; H01L 29/786

(52) U.S. Cl. CPC H10D 84/856; H10D 30/6755; H10D 84/02; H10D 99/00

(57) ABSTRACT

Various embodiments of the present application are directed towards an integrated chip (IC) including a lower dielectric structure over a semiconductor substrate. A gate structure is over the lower dielectric structure. The gate structure comprises a first surface opposite a second surface. A first semiconductor layer is arranged between the first surface of the gate structure and the lower dielectric structure. A second semiconductor layer is over the second surface of the gate structure.

### REFERENCE TO RELATED APPLICATIONS

This application claims the benefit of U.S. Provisional Application No. 63/651,420, filed on May 24, 2024, the contents of which are hereby incorporated by reference in their entirety.

### BACKGROUND

The integrated chip (IC) manufacturing industry has experienced exponential growth over the last few decades. As ICs have evolved, sizes of semiconductor devices (e.g., an area of a transistors) have been scaled down by, for example, reducing minimum feature sizes and/or reducing lateral spacing between adjacent semiconductor devices, which has increased device density (e.g., a number of semiconductor devices integrated in a given area). However, as the lateral spacing between adjacent semiconductor devices continues to be reduced, it is becoming increasingly more difficult to increase device density without negatively affecting performance of the semiconductor devices. Thus, advancements in the IC manufacturing industry that increases device density without negatively impacting the device performance of the semiconductor devices are desired.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip (IC) having an electronic device that comprises transistors vertically stacked with one another over a semiconductor substrate.

FIG. 2 illustrates a cross-section view of some other embodiments of the IC of FIG. 1.

FIGS. 3A-3H illustrate cross-sectional views of some other embodiments of the IC of FIG. 1.

FIGS. 4A-4B illustrate cross-sectional views of some other embodiments of the IC of FIG. 1.

FIGS. 5A-5B illustrate various cross-sectional views of some embodiments of an IC having an electronic device that comprises transistors vertically stacked with one another in a first region of a semiconductor substrate and laterally adjacent to a second region of the semiconductor substrate.

FIGS. 5C-5D illustrate various layout views of some embodiments of the IC of FIG. 5A taken along line A-A′ of FIG. 5A.

FIGS. 6-16 illustrate various cross-sectional views of some embodiments of a first method for forming an IC having an electronic device that comprises transistors vertically stacked with one another.

FIGS. 17-26 illustrate various cross-sectional views of some embodiments of a second method for forming an IC having an electronic device that comprises transistors vertically stacked with one another.

FIGS. 27-38 illustrate various cross-sectional views of some embodiments of a third method for forming an IC having an electronic device that comprises transistors vertically stacked with one another.

FIG. 39 illustrates a flow diagram of some embodiments of a method for forming an IC having an electronic device that comprises transistors vertically stacked with one another.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An integrated chip (IC) may include an electronic device. The electronic device may, for example, be an inverter, latch, logic gate, static random-access memory (SRAM), dynamic random-access memory (DRAM), or some other suitable device. The electronic device comprises a plurality of semiconductor devices. The plurality of semiconductor devices may be or comprise one or more n-channel transistors and one or more p-channel transistors that are electrically coupled in a predefined manner to form the electronic device. Typically, the transistors of the electronic device are disposed in a front-end of line (FEOL) structure on/within a substrate and are formed during a FEOL process.

In an effort to increase device density over the substrate, the transistors of the electronic device may be disposed in a back-end of line (BEOL) structure over the substrate. For example, the electronic device comprises a first gate electrode and a second gate electrode in a dielectric layer over the substrate, where the first and second gate electrodes overlie one or more conductive interconnect structures. A gate dielectric layer overlies the first and second gate electrodes. An n-type semiconductor layer is arranged on the gate dielectric layer over the first gate electrode and a p-type semiconductor layer is arranged on the gate dielectric layer over the second gate electrode. A first pair of source/drain structures is arranged on the n-type semiconductor layer and a second pair of source/drain structures is arranged on the p-type semiconductor layer. The first gate electrode, n-type semiconductor layer, a first segment of the gate dielectric layer, and the first pair of source/drain structures define an n-channel transistor. The second gate electrode, p-type semiconductor layer, a second segment of the gate dielectric layer, and the second pair of source/drain structures define a p-channel transistor. The n-channel transistor is directly laterally adjacent to the p-channel transistor.

Challenges may arise by forming the n-channel transistor and the p-channel transistor laterally adjacent to one another in the BEOL structure. For example, forming the p-type semiconductor layer may include performing a deposition process and/or a doping process at a relatively high temperature (e.g., at a temperature greater than 400 degrees Celsius) that may damage underlying conductive interconnect structure, underlying FEOL devices/structures, and/or other devices (e.g., capacitors, memory devices, etc.) arranged in the BEOL structure. As a result, a yield and/or reliability of the IC may be reduced. Further, in an effort to decrease a lateral footprint of the electric device and increase device density, a lateral distance between the p-type semiconductor layer and the n-type semiconductor layer is relatively small. However, one or more elements in the p-type semiconductor layer may be prone to diffusing or transferring to the n-type semiconductor layer due to the relatively small lateral distance and/or due to interactions with dielectric materials between the n-type and p-type semiconductor layers. This may reduce a performance (e.g., reduce carrier mobility, change a threshold voltage, etc.) of the n-channel transistor and/or the p-channel transistor, thereby decreasing an overall performance of the electronic device.

Various embodiments of the present application are directed towards an integrated chip (IC) comprising an electronic device (e.g., inverter) having transistors vertically stacked with one another over a substrate to increase device density and an overall performance of the electronic device. The transistors of the electronic device comprise an n-channel transistor and a p-channel transistor over one or more conductive interconnect structures over a substrate. The p-channel transistor comprises a first pair of source/drain structures over the one or more conductive interconnect structures, a first semiconductor layer on the first pair of source/drain structures, and a first gate dielectric layer over the first semiconductor layer. A gate electrode overlies the first gate dielectric layer. Further, the n-channel transistor comprises a second gate dielectric layer over the gate electrode, a second semiconductor layer on the second gate dielectric layer, and a second pair of source/drain structures on the second semiconductor layer. The gate electrode is shared by the p-channel and n-channel transistors.

Because the n-channel transistor is vertically stacked over the p-channel transistor, a lateral footprint of the electronic device is decreased, thereby increasing a device density of the IC. Further, the first semiconductor layer of the p-channel transistor is vertically offset from the n-channel transistor by a relatively large distance. As a result, diffusion of one or more elements from the first semiconductor layer to the second semiconductor layer is prevented or mitigated. In addition, dielectric materials of the first and second dielectric layers may be different from one another and are selected to optimize performance for the p-channel and n-channel transistors. Thus, the electronic device comprising the n-channel transistor vertically stacked over the p-channel transistor increases a performance and reliability of the electronic device and a device density of the IC.

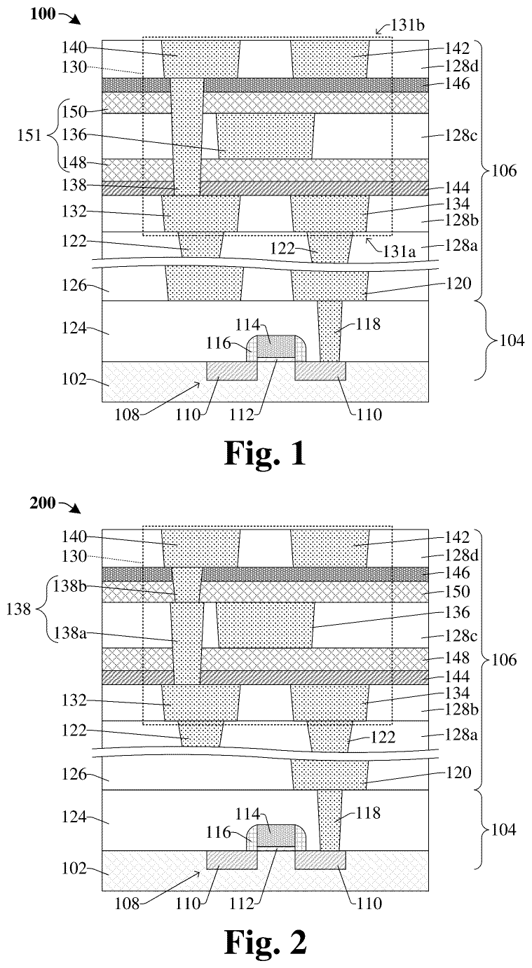

FIG. 1 illustrates a cross-sectional view 100 of some embodiments of an integrated chip (IC) having an electronic device 130 that comprises transistors 131a-b vertically stacked with one another.

The IC comprises a front-end of line (FEOL) structure 104 disposed within and/or on a semiconductor substrate 102 and a back-end of line (BEOL) structure 106 over the FEOL structure 104. The semiconductor substrate 102 may, for example, be or comprise a bulk substrate (e.g., bulk silicon), monocrystalline silicon, silicon-germanium (SiGe), a silicon on insulator (SOI), or the like. The FEOL structure 104 comprises one or more lower semiconductor devices 108 on the semiconductor substrate 102, an inter-level dielectric (ILD) layer 124 over the semiconductor substrate 102, and one or more conductive contacts 118 in the ILD layer 124.

In some embodiments, the one or more lower semiconductor devices 108 are each configured as a transistor such as a metal-oxide-semiconductor field-effect transistor (MOSFET), a fin FET (FinFET), a gate-all-around FET (GAAFET), or the like. In various embodiments, the one or more lower semiconductor devices 108 respectively comprise a pair of source/drain regions 110 in the semiconductor substrate 102, a lower gate electrode 114 over the semiconductor substrate 102 and laterally between the pair of source/drain regions 110, a lower gate dielectric 112 between the lower gate electrode 114 and the semiconductor substrate 102, and a sidewall spacer 116 disposed on sidewalls of the lower gate electrode 114 and the lower gate dielectric 112. Source/drain region(s) may refer to a source or a drain, individually or collectively depending upon the context. The semiconductor substrate 102 may have a first doping type (e.g., p-type). In some embodiments, the pair of source/drain regions 110 are doped regions of the semiconductor substrate 102 that have a second doping type (e.g., n-type) opposite the first doping type. In various embodiments, the first doping type is p-type and the second doping type is n-type, or vice versa. The one or more conductive contacts 118 overlie the semiconductor substrate 102 and are electrically coupled to the one or more lower semiconductor devices 108.

The BEOL structure 106 overlies the semiconductor substrate 102 and comprises a lower dielectric structure 126, a plurality of dielectric layers 128a-d, a plurality of conductive wires 120, and a plurality of conductive vias 122. The plurality of conductive wires 120 and the plurality of conductive vias 122 are configured to electrically couple the electronic device 130 to other semiconductor devices (e.g., the one or more lower semiconductor devices 108 and/or devices on another IC). The plurality of dielectric layers 128a-d includes a first dielectric layer 128a over the lower dielectric structure 126, a second dielectric layer 128b over the first dielectric layer 128a, a third dielectric layer 128c over the second dielectric layer 128b, and a fourth dielectric layer 128d over the third dielectric layer 128c.

The electronic device 130 is disposed in the BEOL structure 106 and directly overlies at least a portion of an individual lower semiconductor device in the one or more lower semiconductor devices 108. The electronic device 130 comprises a plurality of transistors 131a-b vertically stacked with one another. The electronic device 130 may, for example, be or comprise an inverter. In further embodiments, the electronic device 130 may, for example be or comprise a logic gate, a latch, an SRAM cell, some other suitable device, or a combination of the foregoing. In some embodiments, the plurality of transistors 131a-b comprise a p-channel transistor 131a and an n-channel transistor 131b overlying the p-channel transistor 131a. The p-channel transistor 131a and the n-channel transistor 131b may be referred to as semiconductor devices. In various embodiments, the p-channel transistor 131a and the n-channel transistor 131b are each configured as an oxide semiconductor (OS) transistor, a thin-film transistor (TFT), or the like.

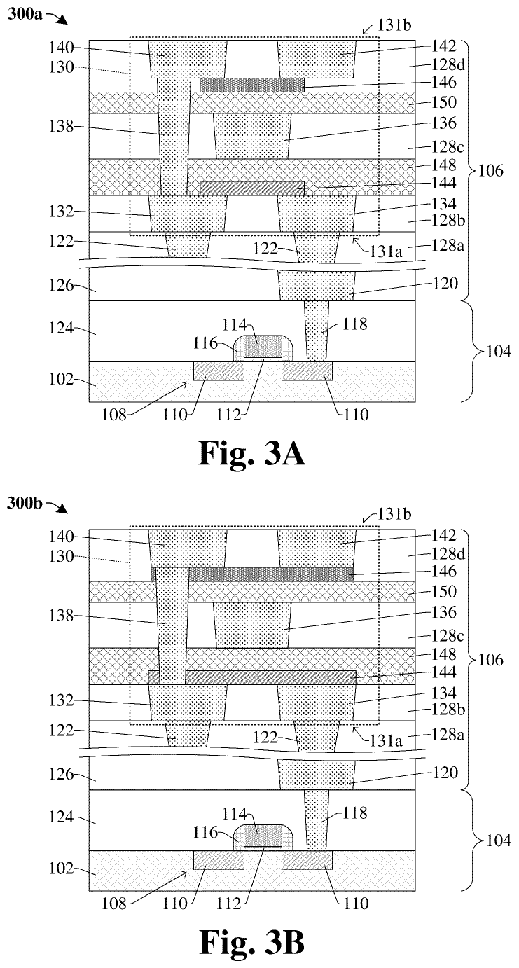

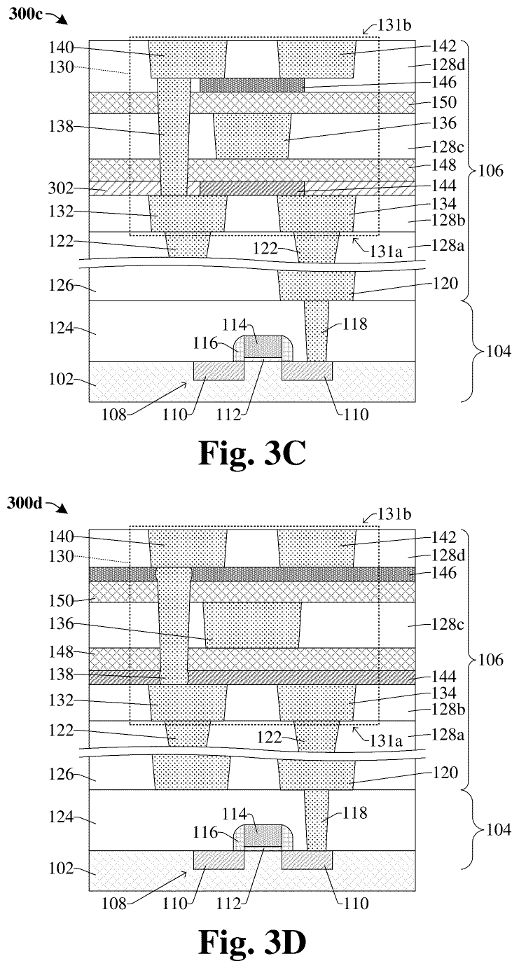

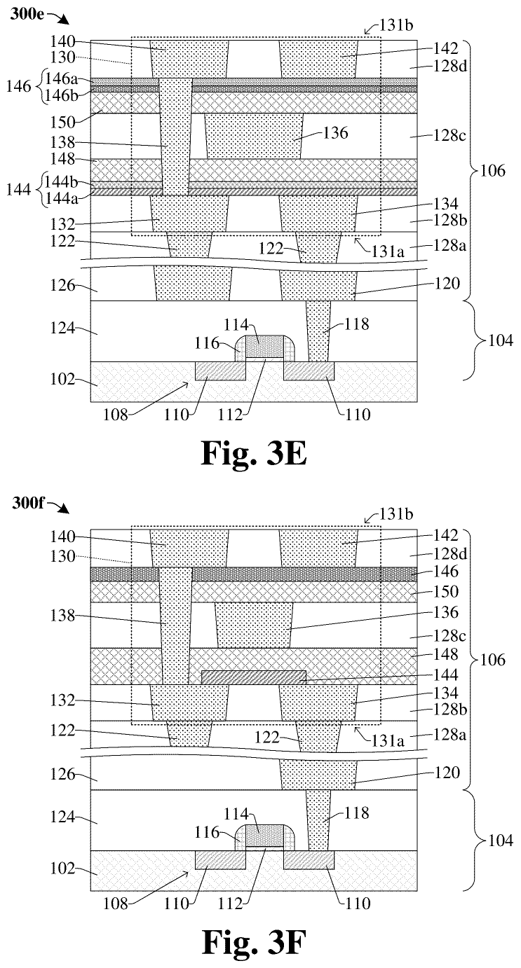

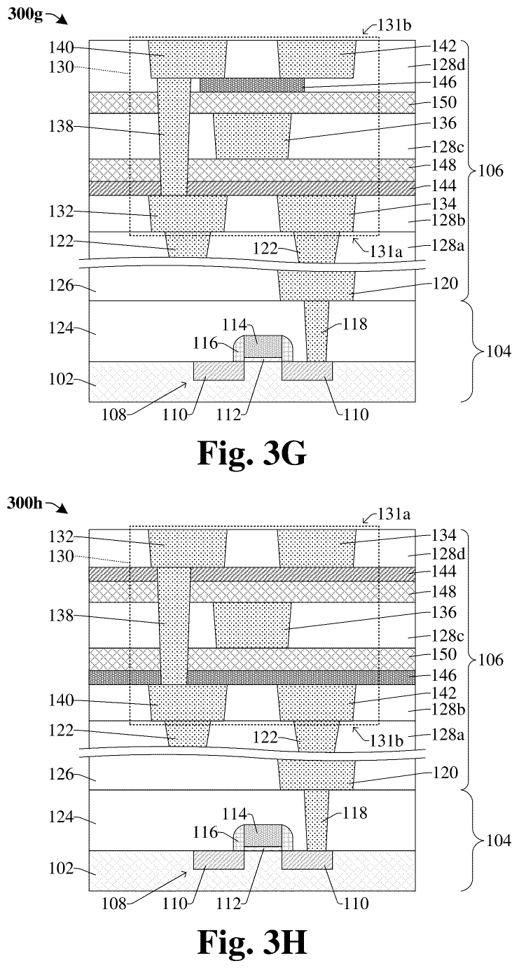

The p-channel transistor 131a comprises a first pair of source/drain structures 132, 134 disposed in the second dielectric layer 128b, a first semiconductor layer 144 on the first pair of source/drain structures 132, 134, and a first gate dielectric layer 148 over the first semiconductor layer 144. Source/drain structure(s) may refer to a source or a drain, individually or collectively depending upon the context. A gate electrode 136 is disposed in the third dielectric layer 128c and overlies the first gate dielectric layer 148. The n-channel transistor 131b comprises a second gate dielectric layer 150 over the gate electrode 136, a second semiconductor layer 146 on the second gate dielectric layer 150, and a second pair of source/drain structures 140, 142 disposed in the fourth dielectric layer 128d and over the second semiconductor layer 146. Further, a conductive source/drain via 138 extends between a first source/drain structure 132 in the first pair of source/drain structure 132, 134 to a first source/drain structure 140 in the second pair of source/drain structures 140, 142. The gate electrode 136 is shared by the p-channel transistor 131a and the n-channel transistor 131b. In some embodiments, the first semiconductor layer 144 comprises a first conductivity type (e.g., p-type) and the second semiconductor layer 146 comprises a second conductivity type (e.g., n-type) opposite the first conductivity type. It will be appreciated that while in various embodiments of the disclosure the n-channel transistor 131b overlies the p-channel transistor 131a, in some embodiments, the vertical stacking may be flipped such that the p-channel transistor 131a overlies the n-channel transistor 131b (e.g., as illustrated and/or described in FIG. 3H).

The electronic device 130 includes a gate structure 151 that comprises the gate electrode 136, the first gate dielectric layer 148, and the second gate dielectric layer. The gate structure 151 has a first surface facing the semiconductor substrate 102 and a second surface facing the second pair of source/drain structure 140, 142. The first semiconductor layer 144 extends along the first surface of the gate structure 151 and the second semiconductor layer 146 extends along the second surface of the gate structure 151. In various embodiments, during operation of the electronic device 130, a first selectively conductive channel may be formed in the first semiconductor layer 144 of the p-channel transistor 131a between the first pair of source/drain structures 132, 134. Further, a second selectively conductive channel may be formed in the second semiconductor layer 146 of the n-channel transistor 131b between the second pair of source/drain structures 140, 142.

Because the n-channel transistor 131b is vertically stacked over the p-channel transistor 131a, a lateral footprint of the electronic device 130 is decreased, thereby increasing a device density of the IC. Further, vertically stacking the p-channel and n-channel transistors 131a, 131b facilitates the first semiconductor layer 144 being offset from the second semiconductor layer 146 by a relatively large distance compared to an embodiment where baseline p-channel and n-channel transistors are spaced directly laterally adjacent to one another on a same plane (not shown). As a result, diffusion of one or more elements from the first semiconductor layer 144 to the second semiconductor layer 146 is mitigated or prevented, thereby increasing a performance of the p-channel and n-channel transistors 131a, 131b. Thus, the electronic device 130 comprising the p-channel transistor 131a vertically stacked with the n-channel transistor 131b increases an overall performance and device density of the IC.

The first semiconductor layer 144 comprises a first metal oxide compound having the first conductivity type (e.g., p-type). In some embodiments, the first semiconductor layer 144 comprises a Cu_{X}Ni_{Y}Sn_{Z}NO compound (where X is within a range of 0 to 1, Y is within a range of 0 to 1, and Z is within a range of 0 to 1), a Cu_{X}Ni_{Y}Sn_{Z}O compound (where X is within a range of 0 to 1, Y is within a range of 0 to 1, and Z is within a range of 0 to 1), or some other suitable material. In various embodiments, Cu is Copper; Ni is Nickel; Sn is Tin; O is Oxygen; and N is Tellurium (Te), Antimony (Sb), Magnesium (Mg), Boron (B), Aluminum (Al), Gallium (Ga), or Iron (Fe). In some embodiments, the first semiconductor layer 144 comprises a single layer comprising the Cu_{X}Ni_{Y}Sn_{Z}NO compound or comprises a multi-layer stack. In various embodiments, layers in the multi-layer stack comprise a different form of the Cu_{X}Ni_{Y}Sn_{Z}NO compound (e.g., each layer comprises different elements in the Cu_{X}Ni_{Y}Sn_{Z}NO compound and/or different concentrations of elements in the Cu_{X}Ni_{Y}Sn_{Z}NO compound). For example, the first semiconductor layer 144 may be or comprise a CuO layer stacked with a NiO layer, a SnO layer stacked with a metal-doped SnO layer, a Cu-rich CuNiO layer stacked with a Cu-poor NiO layer, some other suitable stack of layers, or the like. The first metal oxide of the first semiconductor layer 144 may be a binary compound, a ternary compound, a quaternary compound, a quinary compound, or the like. In yet further embodiments, the first semiconductor layer 144 comprises 1 to 10 metal oxide layers. In yet further embodiments, a thickness of the first semiconductor layer 144 is within a range of about 3 to 10 nanometers (nm) or some other suitable value. In various embodiments, a mobility of charge carriers in the first semiconductor layer 144 is equal to or greater than 6 square centimeters per volt-second (cm²/Vs).

In various embodiments, the first semiconductor layer 144 directly contacts top surfaces of the first pair of source/drain structures 132, 134. In further embodiments, the first semiconductor layer 144 directly contacts opposing sidewalls of the conductive source/drain via 138 and a bottom surface of the first gate dielectric layer 148. The first gate dielectric layer 148 may, for example, be or comprise Aluminum Oxide (Al₂O₃), Hafnium Oxide (HfO₂), Zirconium Oxide (ZrO₂), Hafnium Zirconium Oxide, Hafnium Lanthanum Oxide, Hafnium Silicate Oxide, Hafnium Titanium Oxide, some other suitable dielectric material, or any combination of the foregoing. In various embodiments, the first gate dielectric layer 148 has a dielectric constant greater than 9. In yet further embodiments, the first gate dielectric layer 148 may, for example be or comprise a ferroelectric material (e.g., Lead Zirconate Titanate, Barium Titanate, etc.), an anti-ferroelectric material (e.g., Lead Zirconate, Lead Hafnate, etc.), or the like. In some embodiments, the first gate dielectric layer 148 comprising the ferroelectric material facilitates the p-channel transistor 131a being configured as a capacitorless ferroelectric transistor. A thickness of the first gate dielectric layer 148 is, for example, within a range of 1 to 20 nm or some other suitable value. In various embodiments, the thickness of the first gate dielectric layer 148 is greater than the thickness of the first semiconductor layer 144.

The second semiconductor layer 146 comprises a second metal oxide compound having the second conductivity type (e.g., n-type). In various embodiments, the first metal oxide compound of the first semiconductor layer 144 is different from the second metal oxide compound of the second semiconductor layer 146. In some embodiments, the second semiconductor layer 146 comprises a In_{X}Ga_{Y}Zn_{Z}MO compound (where X is within a range of 0 to 1, Y is within a range of 0 to 1, and Z is within a range of 0 to 1), a In_{X}Ga_{Y}Zn_{Z}O compound (where X is within a range of 0 to 1, Y is within a range of 0 to 1, and Z is within a range of 0 to 1), or some other suitable material. In various embodiments, In is Indium; Ga is Gallium; Zn is Zinc; O is oxygen; and M is Titanium (Ti), Aluminum (Al), Silver (Ag), Tungsten (W), Cerium (Ce), Tin (Sn), Vanadium (V), or Scandium (Sc). In some embodiments, the second semiconductor layer 146 comprises a single layer comprising the In_{X}Ga_{Y}Zn_{Z}MO compound or comprises a multi-layer stack. In various embodiments, layers in the multi-layer stack comprise a different from of the In_{X}Ga_{Y}Zn_{Z}MO compound (e.g., each layer comprises different elements in the In_{X}Ga_{Y}Zn_{Z}MO compound and/or different concentrations of elements in the In_{X}Ga_{Y}Zn_{Z}MO compound). For example, the second semiconductor layer 146 may be or comprise a GaZnO layer stacked with a InZnO layer, a In₁Ga₃Zn₂O layer (e.g., that is Ga-rich) stacked with a InGaZnO layer (e.g., that is Ga-poor), a InGaZnO layer stacked with a Sn-doped InGaZnO layer, some other suitable stack of layers, or the like. The second metal oxide of the second semiconductor layer 146 may be a binary compound, a ternary compound, a quaternary compound, a quinary compound, or the like. In further embodiments, the second semiconductor layer 146 comprises 1 to 10 metal oxide layers. In yet further embodiments, a thickness of the second semiconductor layer 146 is within a range of about 3 to 10 nm or some other suitable value. In various embodiments, a mobility of charge carriers in the second semiconductor layer 146 is equal to or greater than 6 cm²/Vs. In yet further embodiments, the first and second semiconductor layers 144, 146 each have an amorphous-like phase (e.g., at least partially amorphous and/or lacking long-range order found in a crystalline phase), a short-range order phase (e.g., having organization or regularity in the arrangement of atoms or molecules over a few atomic or molecular spacings), or the like. In such embodiments, the first and second semiconductor layers 144, 146 having the amorphous-like phase or the short-range order phase reduces damage to the first and second semiconductor layers 144, 146 during thermal anneal processes while reducing device leakage and/or performance decay in the transistors 131a-b.

In some embodiments, the second semiconductor layer 146 directly contacts bottom surfaces of the second pair of source/drain structures 140, 142. In further embodiments, the second semiconductor layer 146 directly contacts opposing sidewalls of the conductive source/drain via 138 and a top surface of the second gate dielectric layer 150. The second gate dielectric layer 150 may, for example, be or comprise Al₂O₃, HfO₂, ZrO₂, Hafnium Zirconium Oxide, Hafnium Lanthanum Oxide, Hafnium Silicate Oxide, Hafnium Titanium Oxide, some other suitable dielectric material, or any combination of the foregoing. In various embodiments, the second gate dielectric layer 150 has a dielectric constant greater than 9. In yet further embodiments, the second gate dielectric layer 150 may, for example be or comprise a ferroelectric material (e.g., Lead Zirconate Titanate, Barium Titanate, etc.), an anti-ferroelectric material (e.g., Lead Zirconate, Lead Hafnate, etc.), or the like. In some embodiments, the second gate dielectric layer 150 comprising the ferroelectric material facilitates the n-channel transistor 131b being configured as a capacitorless ferroelectric transistor. A thickness of the second gate dielectric layer 150 is, for example, within a range of 1 to 20 nm or some other suitable value. In various embodiments, the thickness of the second gate dielectric layer 150 is greater than the thickness of the second semiconductor layer 146. In yet further embodiments, the first gate dielectric layer 148 comprises a first material and the second gate dielectric layer 150 comprises a second material different from the first material.

The ILD layer 124, the lower dielectric structure 126, and the plurality of dielectric layers 128a-d may, for example, each be or comprise an oxide (e.g., silicon dioxide), a low-k dielectric material, undoped silicate glass, undoped silicon dioxide, some other suitable dielectric, or any combination of the foregoing. As used herein, a low-k dielectric material is a dielectric material with a dielectric constant less than 3.9. In various embodiments, the first pair of source/drain structures 132, 134, the conductive source/drain via 138, the gate electrode 136, and the second pair of source/drain structures 140, 142 may, for example, each be or comprise tantalum nitride, tantalum, titanium, titanium nitride, tungsten, molybdenum, ruthenium, copper, some other conductive material, or any combination of the foregoing. In some embodiments, heights of the first pair of source/drain structures 132, 134, the gate electrode 136, and the second pair of source/drain structures 140, 142 are each within a range of about 5 to 50 nm or some other suitable value. In various embodiments, the height of the gate electrode 136 is greater than a first sum of the thicknesses of the first semiconductor layer 144 and the first gate dielectric layer 148 and is greater than a second sum of the thicknesses of the second semiconductor layer 146 and the second gate dielectric layer 150. In further embodiments, a width of the gate electrode 136 is greater than a width of an individual source/drain structure in the first pair of source/drain structures 132, 134 or in the second pair of source/drain structures 140, 142.

In various embodiments, a distance between the first semiconductor layer 144 and the second semiconductor layer 146 is relatively large (e.g., greater than the height of the gate electrode 136). As a result, diffusion of one or more elements from the first semiconductor layer 144 to the second semiconductor layer 146 is mitigate, thereby increasing a performance of the transistors 131a-b.

FIG. 2 illustrates a cross-sectional view 200 of some other embodiments of the IC of FIG. 1.

In some embodiments, the conductive source/drain via 138 comprises a lower via segment 138a and an upper via segment 138b overlying the lower via segment 138a. The upper via segment 138b directly contacts the lower via segment 138a. The lower via segment 138a extends through the third dielectric layer 128c, the first gate dielectric layer 148, and the first semiconductor layer 144. In various embodiments, a top surface of the lower via segment 138a is coplanar with a top surface of the third dielectric layer 128c and a top surface of the gate electrode 136. The upper via segment 138b extends through the second gate dielectric layer 150 and the second semiconductor layer 146. In some embodiments, a top surface of the upper via segment 138b is coplanar with a top surface of the second semiconductor layer 146. The conductive source/drain via 138 directly electrically couples a first source/drain structure 132 in the first pair of source/drain structures 132, 134 to a first source/drain structure 140 in the second pair of source/drain structures 140, 142.

In some embodiments, the electronic device 130 is configured as an inverter. The gate electrode 136 is electrically coupled to an input voltage node configured to receive an input voltage Vin. In various embodiments, the gate electrode 136 is electrically coupled to a conductive via (not shown) in a location laterally offset from the electronic device 130. The first source/drain structure 132 in the first pair of source/drain structures 132, 134 and the first source/drain structure 140 in the second pair of source/drain structures 140, 142 is electrically coupled to an output voltage node. A second source/drain structure 134 in the first pair of source/drain structures 132, 134 is electrically coupled to a first supply voltage node (e.g., Vdd) that may be coupled to a supply voltage that is about 1.8 volts (V), 3.3 V, 5 V, within a range of about 1.8 to 15 V, or some other suitable value. A second source/drain structure 142 in the second pair of source/drain structures 140, 142 is electrically coupled to a reference voltage node (e.g., Vss) that may be ground (e.g., OV) or some other suitable value. In some embodiments, an individual source/drain region in the pair of source/drain regions 110 of a semiconductor device in the one or more lower semiconductor devices 108 is directly electrically coupled to the gate electrode 136.

FIG. 3A illustrates a cross-sectional view 300a of some other embodiments of the IC of FIG. 1.

In some embodiments, outer sidewalls of the first semiconductor layer 144 are spaced between the first pair of source/drain structures 132, 134. A first outer sidewall of the first semiconductor layer 144 directly overlies a first source/drain structure 132 in the first pair of source/drain structures 132, 134 and a second outer sidewall of the first semiconductor layer 144 directly overlies a second source/drain structure 134 in the first pair of source/drain structures 132, 134. Further, the first semiconductor layer 144 may be laterally offset from the conductive source/drain via 138 by a non-zero distance. In such embodiments, this may reduce damage to the first semiconductor layer 144 while forming the conductive source/drain via 138 (e.g., reduce damage from an etching process utilized to form an opening for the conductive source/drain via 138). In various embodiments, the first gate dielectric layer 148 directly contacts the outer sidewalls and the top surface of the first semiconductor layer 144. A bottom surface of the first gate dielectric layer 148 may be aligned with a bottom surface of the first semiconductor layer 144. In some embodiments, spacing the outer sidewalls of the first semiconductor layer 144 between the first pair of source/drain structures 132, 134 increases isolation between the p-channel transistor 131a and other transistors (not shown) disposed in the BEOL structure 106 at a same level as the p-channel transistor 131a.

In some embodiments, outer sidewalls of the second semiconductor layer 146 are spaced between the second pair of source/drain structures 140, 142. A first outer sidewall of the second semiconductor layer 146 directly underlies a first source/drain structure 140 in the second pair of source/drain structures 140, 142 and a second outer sidewall of the second semiconductor layer 146 directly underlies a second source/drain structure 142 in the second pair of source/drain structures 140, 142. The second semiconductor layer 146 may be laterally offset from the conductive source/drain via 138 by a non-zero distance. In such embodiments, this may reduce damage to the second semiconductor layer 146 while forming the conductive source/drain via 138 (e.g., reduce damage from an etching process utilized to form an opening for the conductive source/drain via 138). In various embodiments, the fourth dielectric layer 128d directly contacts the outer sidewalls and the top surface of the second semiconductor layer 146. A bottom surface of the fourth dielectric layer 128d may be aligned with a bottom surface of the second semiconductor layer 146. In some embodiments, spacing the outer sidewalls of the second semiconductor layer 146 between the second pair of source/drain structures 140, 142 increases isolation between the n-channel transistor 131b and other transistors (not shown) disposed in the BEOL structure 106 at a same level as the n-channel transistor 131b.

The bottom surface of the first gate dielectric layer 148 directly contacts a portion of a top surface of the first source/drain structure 132 in the first pair of source/drain structures 132, 134 and a portion of a top surface of the second source/drain structure 134 in the first pair of source/drain structures 132, 134. The fourth dielectric layer 128d directly contacts a portion of a bottom surface of the first source/drain structure 140 in the second pair of source/drain structures 140, 142 and a portion of a bottom surface of the second source/drain structure 142 in the second pair of source/drain structures 140, 142. In various embodiments, a thickness of the first gate dielectric layer 148 is greater than a thickness of the second gate dielectric layer 150. In further embodiments, the thickness of the second gate dielectric layer 150 is greater than the thickness of the first semiconductor layer 144 and the thickness of the second semiconductor layer 146. In yet further embodiments, centers of the first and second semiconductor layers 144, 146 are aligned with a center of the gate electrode 136.

FIG. 3B illustrates a cross-sectional view 300b of some other embodiments of the IC of FIG. 1.

In some embodiments, a first outer sidewall of the first semiconductor layer 144 is aligned with an outer edge and/or an outer sidewall of the first source/drain structure 132 in the first pair of source/drain structures 132, 134. A second outer sidewall of the first semiconductor layer 144 is aligned with an outer edge and/or an outer sidewall of the second source/drain structure 134 in the first pair of source/drain structures 132, 134. Further, a first outer sidewall of the second semiconductor layer 146 is aligned with an outer edge and/or an outer sidewall of the first source/drain structure 140 in the second pair of source/drain structures 140, 142. A second outer sidewall of the second semiconductor layer 146 is aligned with an outer edge and/or an outer sidewall of the second source/drain structure 142 in the second pair of source/drain structures 140, 142.

FIG. 3C illustrates a cross-sectional view 300c of some other embodiments of the IC of FIG. 3A, where an intermediate dielectric layer 302 is disposed around the outer sidewalls of the first semiconductor layer 144.

In some embodiments, the intermediate dielectric layer 302 is disposed between the first gate dielectric layer 148 and the first pair of source/drain structures 132, 134. The intermediate dielectric layer 302 directly contacts the outer sidewalls of the first semiconductor layer 144. The intermediate dielectric layer 302 may, for example, be or comprise silicon dioxide, a low-k dielectric material, silicon nitride, silicon carbide, some other suitable dielectric material, or any combination of the foregoing.

FIG. 3D illustrates a cross-sectional view 300d of some other embodiments of the IC of FIG. 1.

In some embodiments, the conductive source/drain via 138 comprises a first pair of sidewall segments that are curved and meet curved sidewalls of the first semiconductor layer 144. Further the conductive source/drain via 138 comprises a second pair of sidewall segments that are curved and meet curved sidewalls of the second semiconductor layer 146.

FIG. 3E illustrates a cross-sectional view 300e of some other embodiments of the IC of FIG. 1.

In various embodiments, the first semiconductor layer 144 comprises a first metal oxide layer 144a and a second metal oxide layer 144b comprising a different material than the first metal oxide layer 144a. In some embodiments, the first metal oxide layer 144a comprises CuO and the second metal oxide layer 144b comprises NiO; the first metal oxide layer 144a comprises SnO and the second metal oxide layer 144b comprises metal-doped SnO; the first metal oxide layer 144a comprises Cu-rich CuNiO and the second metal oxide layer 144b comprises Cu-poor NiO; or the like.

In further embodiments, the second semiconductor layer 146 comprises a first metal oxide layer 146a and a second metal oxide layer 146b comprising a different material than the first metal oxide layer 146a. In some embodiments, the first metal oxide layer 146a comprises GaZnO and the second metal oxide layer 146b comprises InZnO; the first metal oxide layer 146a comprises In₁Ga₃Zn₂O and the second metal oxide layer 146b comprises InGaZnO; the first metal oxide layer 146a comprises InGaZnO and the second metal oxide layer 146b comprises Sn-doped InGaZnO; or the like. While FIG. 3E shows the first and second semiconductor layers 144, 146 having two different layers, it will be appreciated that this is a non-limiting example and the first and second semiconductor layers 144, 146 may comprise any number of layers.

FIG. 3F illustrates a cross-sectional view 300f of some other embodiments of the IC of FIG. 1.

In some embodiments, outer sidewalls of the first semiconductor layer 144 are spaced between the first pair of source/drain structures 132, 134 and the second pair of source/drain structures 140, 142 are spaced between outer sidewalls of the second semiconductor layer 146. The outer sidewalls of the second semiconductor layer 146 are aligned with outer sidewalls of the second gate dielectric layer 150. In various embodiments, the first semiconductor layer 144 may be configured as illustrated and/or described in FIG. 3A. In some embodiments, during fabrication of the IC of FIG. 3F, the first semiconductor layer 144 is deposited and subsequently patterned to define the outer sidewalls of the first semiconductor layer 144 between the first pair of source/drain structure 132, 134.

FIG. 3G illustrates a cross-sectional view 300g of some other embodiments of the IC of FIG. 1.

In some embodiments, the first pair of source/drain structures 132, 134 are spaced between outer sidewalls of the first semiconductor layer 144 and outer sidewalls of the second semiconductor layer 146 are spaced between the second pair of source/drain structures 140, 142. The outer sidewalls of the first semiconductor layer 144 are aligned with outer sidewalls of the first gate dielectric layer 148. In various embodiments, the second semiconductor layer 146 may be configured as illustrated and/or described in FIG. 3A. In some embodiments, during fabrication of the IC of FIG. 3F, the second semiconductor layer 146 is deposited and subsequently patterned to define the outer sidewalls of the second semiconductor layer 146 between the second pair of source/drain structure 140, 142.

FIG. 3H illustrates a cross-sectional view 300h of some other embodiments of the IC of FIG. 1.

In some embodiments, the p-channel transistor 131a overlies the n-channel transistor 131b. In such embodiments, the second semiconductor layer 146 overlies the second pair of source/drain structures 140, 142 and the second gate dielectric layer 150 is disposed between the top surface of the second semiconductor layer 146 and a bottom surface of the gate electrode 136. Further, the first gate dielectric layer 148 is disposed between a top surface of the gate electrode 136 and a bottom surface of the first semiconductor layer 144, and the first pair of source/drain structures 132, 134 overlie the first semiconductor layer 144.

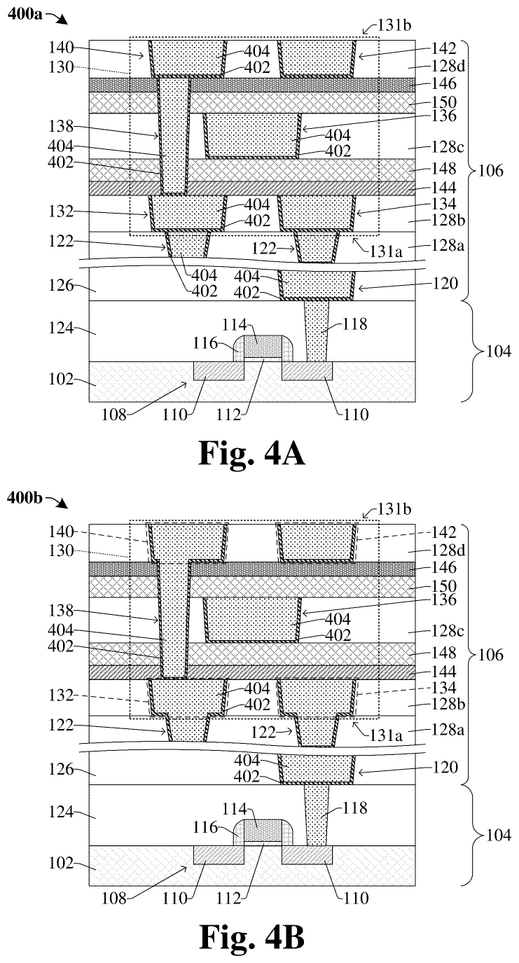

FIG. 4A illustrates a cross-sectional view 400a of some other embodiments of the IC of FIG. 1.

In some embodiments, the plurality of conductive wires and vias 120, 122, the first pair of source/drain structures 132, 134, the gate electrode 136, the conductive source/drain via 138, and the second pair of source/drain structures 140, 142 respectively comprise a conductive body structure 404 and a conductive liner 402. The conductive liner 402 is disposed along opposing sidewalls and a bottom surface of the conductive body structure 404. The conductive body structure 404 may, for example, be or comprise copper, aluminum, tungsten, ruthenium, some other conductive material, or any combination of the foregoing. The conductive liner 402 may, for example, be or comprise titanium, titanium nitride, tantalum, tantalum nitride, some other suitable conductive material, or any combination of the foregoing. The conductive liner 402 may be configured as a diffusion barrier layer and/or an adhesion layer.

FIG. 4B illustrates a cross-sectional view 400b of some other embodiments of the IC of FIG. 4A.

In some embodiments, the first pair of source/drain structures 132, 134 respectively share a corresponding conductive body structure 404 and conductive liner 402 with an underlying conductive via 122. In further embodiments, the first source/drain structure 140 in the second pair of source/drain structures 140, 142 shares a corresponding conductive body structure 404 and conductive liner 402 with the conductive source/drain via 138.

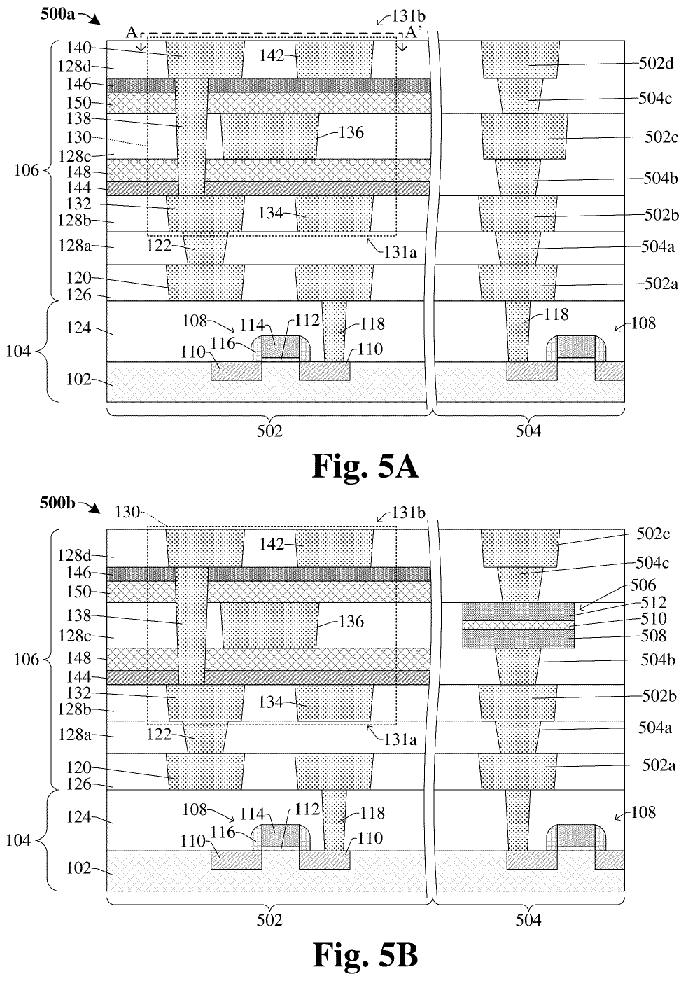

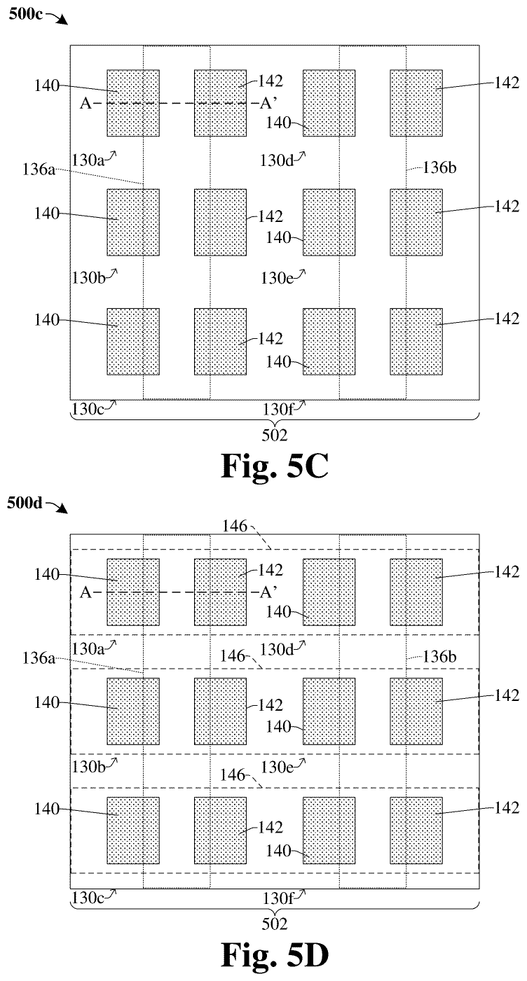

FIG. 5A illustrates a cross-sectional view 500a of some embodiments of an IC having an electronic device that comprises transistors vertically stacked with one another in a first region of a semiconductor substrate laterally adjacent to a second region of the semiconductor substrate.

The semiconductor substrate 102 comprises a first region 502 laterally adjacent to a second region 504. In some embodiments, the electronic device 130 is arranged in the first region 502. The electronic device 130 comprises the p-channel transistor 131a and the n-channel transistor 131b overlying the p-channel transistor 131a. The second region 504 may comprise one or more of the lower semiconductor devices 108 on the semiconductor substrate 102 and a second plurality of conductive wires 502a-d and a second plurality of conductive vias 504a-c.

The second plurality of conductive wires 502a-d and the second plurality of conductive vias 504a-c are arranged in different levels. For example, a first conductive wire 502a is arranged in a first wire level, a second conductive wire 502b is arranged in a second wire level, a third conductive wire 502c is arranged in a third wire level, and a fourth conductive wire 502d is arranged in a fourth wire level. In some embodiments, the first pair of source/drain structures 132, 134, the gate electrode 136, and the second pair of source/drain structures 140, 142 may be configured as conductive wires aligned with a corresponding conductive wire in the second plurality of conductive wires 502a-d. In various embodiments, the first pair of source/drain structures 132, 134 is aligned with and/or arranged in the second wire level. For example, a bottom surface of the second conductive wire 502b is aligned with bottom surfaces of the first pair of source/drain structures 132, 134. In further embodiments, the gate electrode 136 is aligned with and/or arranged in the third wire level and the second pair of source/drain structures 140, 142 is aligned with and/or arranged in the fourth wire level.

FIG. 5B illustrates a cross-sectional view 500b of some embodiments of the IC of FIG. 5A.

In some embodiments, a BEOL device 506 is arranged in the second region 504 adjacent to the electronic device 130. In some embodiments, the BEOL device 506 is configured as a capacitor, a memory device, or some other electronic device. The BEOL device 506 may, for example, comprise a dielectric layer 510 arranged between a bottom electrode 508 and a top electrode 512. In various embodiments, the dielectric layer 510 is configured as a data storage layer, a capacitor dielectric, or the like.

FIG. 5C illustrates a layout view 500c of some embodiments of the IC of FIG. 5A taken along the line A-A′.

In some embodiments, the IC comprises a plurality of electronic devices 130a-f arranged in the BEOL structure (106 of FIG. 5A). In various embodiments, the plurality of electronic devices 130a-f are each configured as illustrated and/or described in FIG. 1, 2, 3A-3E, 4A-4B, or 5A-5B. The plurality of electronic devices 130a-f comprise a first column of electronic devices 130a-c and a second column of electronic devices 130d-f. The first column of electronic devices 130a-c share a first gate electrode 136a that is elongated across a length of the first column of electronic devices 130a-c. The second column of electronic devices 130d-f share a second gate electrode 136b. The first and second gate electrodes 136a-b are each represented as a dashed box in the layout view 500c. In various embodiments, the first and second gate electrodes 136a-b are electrically coupled to a conductive via (not shown) in a location laterally offset from the plurality of electronic devices 130a-f. In some embodiments, the second pair of source/drain structures 140, 132 of each of the electronic devices 130a-f are respectively elongated in a same direction as the first and second gate electrodes 136a-b are elongated. In further embodiments, the first pair of source/drain structures (e.g., 132, 134 of FIG. 5A) of each electronic device 130a-f directly underlie the second pair of source/drain structures 140, 142.

FIG. 5D illustrates a layout view 500d of some other embodiments of the IC of FIG. 5C. The layout view 500d is taken along the line A-A′ of FIG. 5A.

In some embodiments, rows of the plurality of electronic devices 130a-f share a corresponding second semiconductor layer 146 and first semiconductor layer (e.g., first semiconductor layer 144 of FIG. 5A) that are elongated in a first direction. In various embodiments, the first and second gate electrodes 136a-b are elongated in a second direction that is perpendicular to the first direction.

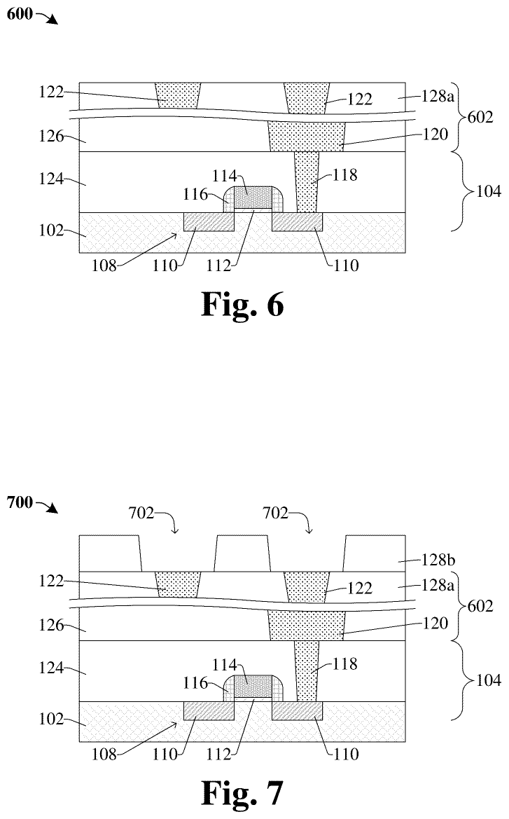

FIGS. 6-16 illustrate cross-sectional views 600-1600 of some embodiments of a first method for forming an integrated chip (IC) having an electronic device that comprises transistors vertically stacked with one another according to the present disclosure. Although the cross-sectional views 600-1600 shown in FIGS. 6-16 are described with reference to a first method, it will be appreciated that the structures shown in FIGS. 6-16 are not limited to the first method but rather may stand alone separate of the first method. Furthermore, although FIGS. 6-16 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 600 of FIG. 6, a semiconductor substrate 102 is provided and a FEOL structure 104 and a lower BEOL structure 602 are formed on the semiconductor substrate 102. The semiconductor substrate 102 may, for example, be or comprise a bulk substrate (e.g., bulk silicon), monocrystalline silicon, SiGe, a SOI, or the like. The FEOL structure 104 comprises a semiconductor device 108 on the semiconductor substrate 102, an ILD layer 124 over the semiconductor substrate 102, and one or more conductive contacts 118 in the ILD layer 124. The lower BEOL structure 602 may be referred to as a lower interconnect structure.

In various embodiments, the semiconductor device 108 comprises a pair of source/drain regions 110, a lower gate electrode 114, a lower gate dielectric 112, and a sidewall spacer 116. In some embodiments, a process for forming the semiconductor device 108 comprises: depositing (e.g., by chemical vapor deposition (CVD), physical vapor deposition (PVD), atomic layer deposition (ALD), thermal oxidation, etc.) a gate dielectric material on the semiconductor substrate 102; depositing (e.g., by CVD, PVD, ALD, etc.) a gate electrode material on the gate dielectric material; etching the gate dielectric material and the gate electrode material to form the lower gate electrode 114 and the lower gate dielectric 112; depositing a sidewall spacer material on the lower gate electrode 114 and the lower gate dielectric 112; etching the sidewall spacer material to form the sidewall spacer 116; and performing a selective ion implantation process to from the pair of source/drain regions 110 in the semiconductor substrate 102 on opposing sides of the lower gate electrode 114. The ILD layer 124 is, for example, formed on the semiconductor substrate 102 by a CVD process, a PVD process, an ALD process, or some other suitable growth or deposition process. Further, the one or more conductive contacts 118 may be formed by etching the ILD layer 124 to form openings in the ILD layer 124, depositing (e.g., by CVD, PVD, ALD, etc.) a conductive material in the openings, and performing a planarization process (e.g., a chemical mechanical planarization (CMP) process) on the conductive material.

Further, the lower BEOL structure 602 comprises a lower dielectric structure 126, a plurality of conductive wires 120, a first dielectric layer 128a, and a plurality of conductive vias 122. The lower dielectric structure 126 and the first dielectric layer 128a may, for example, each be formed by a CVD process, a PVD process, an ALD process, or some other suitable growth or deposition process. The plurality of conductive wires 120 and the plurality of conductive vias 122 may, for example, be formed by a single damascene process, a dual damascene process, or some other suitable process.

As shown in the cross-sectional view 700 of FIG. 7, a second dielectric layer 128b is formed over the first dielectric layer 128a and a plurality of openings 702 are formed in the second dielectric layer 128b. The second dielectric layer 128b may, for example, be formed by a CVD process, a PVD process, an ALD process, or some other suitable growth or deposition process. In some embodiments, a process for forming the plurality of openings 702 includes: forming a masking layer (not shown) on the second dielectric layer 128b; etching the second dielectric layer 128b; and performing a removal process to remove the masking layer.

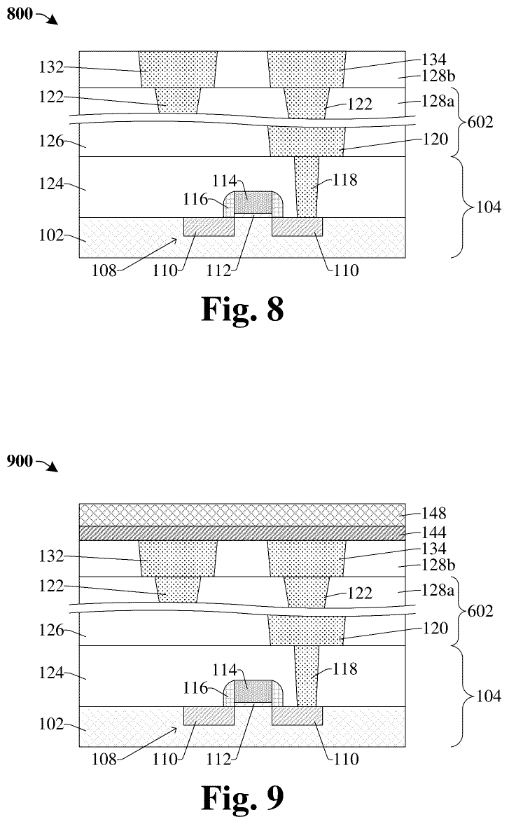

As shown in the cross-sectional view 800 of FIG. 8, a first pair of source/drain structures 132, 134 is formed in the second dielectric layer 128b. In some embodiments, a process for forming the first pair of source/drain structures 132, 134 includes depositing (e.g., by CVD, PVD, ALD, etc.) one or more conductive materials in the plurality of openings (702 of FIG. 7) and performing a planarization process (e.g., a CMP process) on the one or more conductive materials. In various embodiments, depositing the one or more conductive materials includes depositing a conductive liner layer (e.g., comprising titanium nitride, tantalum nitride, etc.) lining the openings (702 of FIG. 7) and depositing a conductive core (e.g., copper, aluminum, tungsten, some other conductive material, or any combination of the foregoing) over the conductive liner layer.

As shown in the cross-sectional view 900 of FIG. 9, a first semiconductor layer 144 is formed on the first pair of source/drain structures 132, 134 and a first gate dielectric layer 148 is formed on the first semiconductor layer 144. In some embodiments, the first semiconductor layer 144 is formed by one or more deposition processes that may include one or more of a PVD process, a CVD process, an ALD process, or some other suitable growth or deposition process. Further, the one or more deposition processes is/are performed at a first deposition temperature that is, for example, less than or equal to about 400 degrees Celsius. By forming the first semiconductor layer 144 at the first deposition temperature, damage to structures in the lower BEOL structure 602 and/or the FEOL structure 104 may be mitigated or reduced. The first semiconductor layer 144 comprises a first conductivity type (e.g., p-type). In various embodiments, the first semiconductor layer 144 is formed to a thickness within a range of about 3 to 10 nm or some other suitable value. Further, the first semiconductor layer 144 may, for example, be or comprise a Cu_{X}Ni_{Y}Sn_{Z}NO compound (where X is within a range of 0 to 1, Y is within a range of 0 to 1, and Z is within a range of 0 to 1), a Cu_{X}Ni_{Y}Sn_{Z}O compound (where X is within a range of 0 to 1, Y is within a range of 0 to 1, and Z is within a range of 0 to 1), or some other suitable material. In various embodiments, Cu is Copper; Ni is Nickel; Sn is Tin; O is Oxygen; and N is Tellurium (Te), Antimony (Sb), Magnesium (Mg), Boron (B), Aluminum (Al), Gallium (Ga), or Iron (Fe). In some embodiments, the first semiconductor layer 144 comprises a single layer comprising the Cu_{X}Ni_{Y}Sn_{Z}NO compound or comprises a multi-layer stack.

In some embodiments, the first gate dielectric layer 148 is formed on the first semiconductor layer 144 by, for example, a PVD process, a CVD process, an ALD process, or some other suitable growth or deposition process. The first gate dielectric layer 148 may, for example, be or comprise Aluminum Oxide (Al₂O₃), Hafnium Oxide (HfO₂), Zirconium Oxide (ZrO₂), Hafnium Zirconium Oxide, Hafnium Lanthanum Oxide, Hafnium Silicate Oxide, Hafnium Titanium Oxide, some other suitable dielectric material, or any combination of the foregoing. In various embodiments, the first gate dielectric layer 148 has a dielectric constant greater than 9. In yet further embodiments, the first gate dielectric layer 148 may, for example be or comprise a ferroelectric material (e.g., Lead Zirconate Titanate, Barium Titanate, etc.), an anti-ferroelectric material (e.g., Lead Zirconate, Lead Hafnate, etc.), or the like. In further embodiments, a thickness of the first gate dielectric layer 148 is greater than the thickness of the first semiconductor layer 144.

In various embodiments, a patterning process may be performed on the first semiconductor layer 144 before forming the first gate dielectric layer 148 on the first semiconductor layer 144. In such embodiments, the first gate dielectric layer 148 extends along and contacts outer sidewalls of the first semiconductor layer 144 (e.g., as illustrated and/or described in FIG. 3A). In some embodiments, the patterning process includes: forming a masking layer (not shown) over the first semiconductor layer 144; etching the first semiconductor layer 144 according to the masking layer; and removing the masking layer.

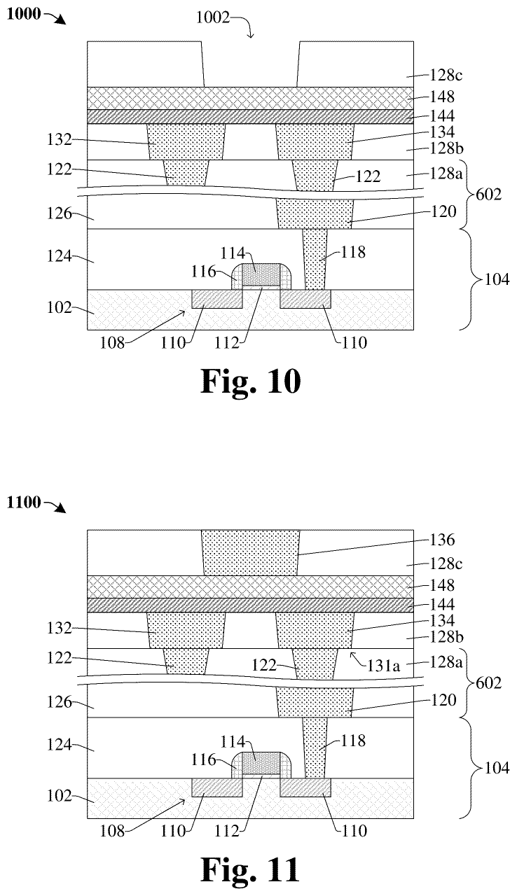

As shown in the cross-sectional view 1000 of FIG. 10, a third dielectric layer 128c is formed over the first gate dielectric layer 148 and an opening 1002 is formed in the third dielectric layer 128c. The third dielectric layer 128c may, for example, be formed by a CVD process, a PVD process, an ALD process, or some other suitable growth or deposition process. In some embodiments, a process for forming the opening 1002 includes: forming a masking layer (not shown) on the third dielectric layer 128c; etching the third dielectric layer 128c; and performing a removal process to remove the masking layer.

As shown in the cross-sectional view 1100 of FIG. 11, a gate electrode 136 is formed in the third dielectric layer 128c, thereby forming a p-channel transistor 131a over the lower BEOL structure 602. In some embodiments, a process for forming the gate electrode 136 includes depositing (e.g. by CVD, PVD, ALD, etc.) one or more conductive materials in the opening (1002 of FIG. 10) and performing a planarization process (e.g., a CMP process) on the one or more conductive materials. In various embodiments, depositing the one or more conductive materials includes depositing a conductive liner layer (e.g., comprising titanium nitride, tantalum nitride, etc.) lining the opening (1002 of FIG. 10) and depositing a conductive core (e.g., copper, aluminum, tungsten, some other conductive material, or any combination of the foregoing) over the conductive liner layer. In some embodiments, a process for forming the p-channel transistor 131a includes the processing steps illustrated and/or described in FIGS. 7-11.

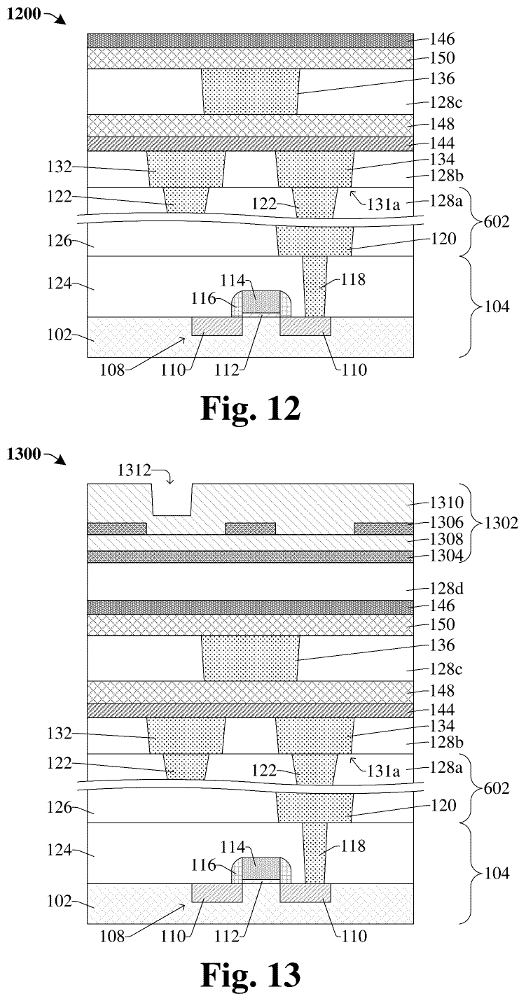

As shown in the cross-sectional view 1200 of FIG. 12, a second gate dielectric layer 150 is formed over the gate electrode 136 and a second semiconductor layer 146 is formed on the second gate dielectric layer 150. In some embodiments, the second gate dielectric layer 150 is formed on the gate electrode 136 by, for example, a PVD process, a CVD process, an ALD process, or some other suitable growth or deposition process. In some embodiments, the second semiconductor layer 146 is formed by one or more deposition processes that may include one or more of a PVD process, a CVD process, an ALD process, or some other suitable growth or deposition process. Further, the one or more deposition processes is/are performed at a second deposition temperature that is, for example, less than or equal to about 400 degrees Celsius. By forming the second semiconductor layer 146 at the second deposition temperature, damage to structures in the lower BEOL structure 602, the FEOL structure 104, and/or the p-channel transistor 131a may be mitigated or reduced. The second semiconductor layer 146 comprises a second conductivity type (e.g., n-type). In various embodiments, the second semiconductor layer 146 is formed to a thickness within a range of about 3 to 10 nm or some other suitable value. Further, the second semiconductor layer 146 may, for example, be or comprise a In_{X}Ga_{Y}Zn_{Z}MO compound (where X is within a range of 0 to 1, Y is within a range of 0 to 1, and Z is within a range of 0 to 1), a In_{X}Ga_{Y}Zn_{Z}O compound (where X is within a range of 0 to 1, Y is within a range of 0 to 1, and Z is within a range of 0 to 1), or some other suitable material. In various embodiments, In is Indium; Ga is Gallium; Zn is Zinc; O is oxygen; and M is Titanium (Ti), Aluminum (Al), Silver (Ag), Tungsten (W), Cerium (Ce), Tin (Sn), Vanadium (V), or Scandium (Sc). In some embodiments, the first semiconductor layer 144 comprises a single layer comprising the In_{X}Ga_{Y}Zn_{Z}MO compound or comprises a multi-layer stack.

In some embodiments, the second gate dielectric layer 150 may, for example, be or comprise Aluminum Oxide (Al₂O₃), Hafnium Oxide (HfO₂), Zirconium Oxide (ZrO₂), Hafnium Zirconium Oxide, Hafnium Lanthanum Oxide, Hafnium Silicate Oxide, Hafnium Titanium Oxide, some other suitable dielectric material, or any combination of the foregoing. In various embodiments, the second gate dielectric layer 150 has a dielectric constant greater than 9. In yet further embodiments, the second gate dielectric layer 150 may, for example be or comprise a ferroelectric material (e.g., Lead Zirconate Titanate, Barium Titanate, etc.), an anti-ferroelectric material (e.g., Lead Zirconate, Lead Hafnate, etc.), or the like. In further embodiments, a thickness of the second gate dielectric layer 150 is greater than the thickness of the second semiconductor layer 146.

In various embodiments, a patterning process may be performed on the second semiconductor layer 146. In such embodiments, outer sidewalls of the second semiconductor layer 146 are spaced between outer sidewalls of the second gate dielectric layer 150 (e.g., as illustrated and/or described in FIG. 3A). In some embodiments, the patterning process includes: forming a masking layer (not shown) over the second semiconductor layer 146; etching the second semiconductor layer 146 according to the masking layer; and removing the masking layer.

As shown in the cross-sectional view 1300 of FIG. 13, a fourth dielectric layer 128d is formed over the second semiconductor layer 146 and a masking structure 1302 is formed on the fourth dielectric layer 128d. In some embodiments, the masking structure 1302 comprises a first hard mask 1304 on the fourth dielectric layer 128d, a first photoresist 1308 on the first hard mask 1304, a patterned hard mask 1306 over the first photoresist 1308, and a second photoresist 1310 over the patterned hard mask 1306. The second photoresist 1310 comprises sidewalls defining an opening 1312 over an individual source/drain structure 132 in the first pair of source/drain structures 132, 134. The fourth dielectric layer 128d may, for example, be formed by a CVD process, a PVD process, an ALD process, or some other suitable growth or deposition process.

In some embodiments, the first hard mask 1304 and the patterned hard mask 1306 may, for example, each be or comprise titanium, titanium nitride, tungsten, some other metal, some other suitable material, or any combination of the foregoing. In various embodiments, a process for forming the masking structure 1302 includes: depositing (e.g., by CVD, PVD, etc.) the first hard mask 1304 over the fourth dielectric layer 128d; depositing (e.g., by spin coating or another suitable process) the first photoresist 1308 on the first hard mask 1304; depositing (e.g., by CVD, PVD, etc.) a second hard mask over the first photoresist 1308; patterning the second hard mask to form or define the patterned hard mask 1306; depositing (e.g., by spin coating or another suitable process) the second photoresist 1310 on the patterned hard mask 1306; and forming (e.g., by a photolithography process or another suitable process) the opening 1312 in the second photoresist 1310.

As shown in the cross-sectional view 1400 of FIG. 14, a first etching process is performed on the first semiconductor layer 144, the first gate dielectric layer 148, the third dielectric layer 128c, the second gate dielectric layer 150, the second semiconductor layer 146, and the fourth dielectric layer 128d according to the masking structure 1302, thereby forming a via opening 1402. The via opening 1402 exposes an upper surface of the individual source/drain structure 132 in the first pair of source/drain structures 132, 134. In some embodiments, the first etching process includes a dry etch process (e.g., a reactive ion etch (RIE) process, a deep reactive ion etch (DRIE) process, a plasma etch process, etc.), a wet etch process, some other suitable etch process, or any combination of the foregoing. In various embodiments, the first and second semiconductor layers 144, 146 may be etched more quickly (e.g., have a higher etching selectivity) than the first and second gate dielectric layers 148, 150 and/or the third and fourth dielectric layers 128c, 128d during the first etching process. In such embodiments, inner sidewalls of the first and second semiconductor layers 144, 146 defining at least a portion of the via opening 1402 may be recessed (e.g., as illustrated and/or described in FIG. 3D). In various embodiments, the first etching process reduces a thickness of the second photoresist 1310.

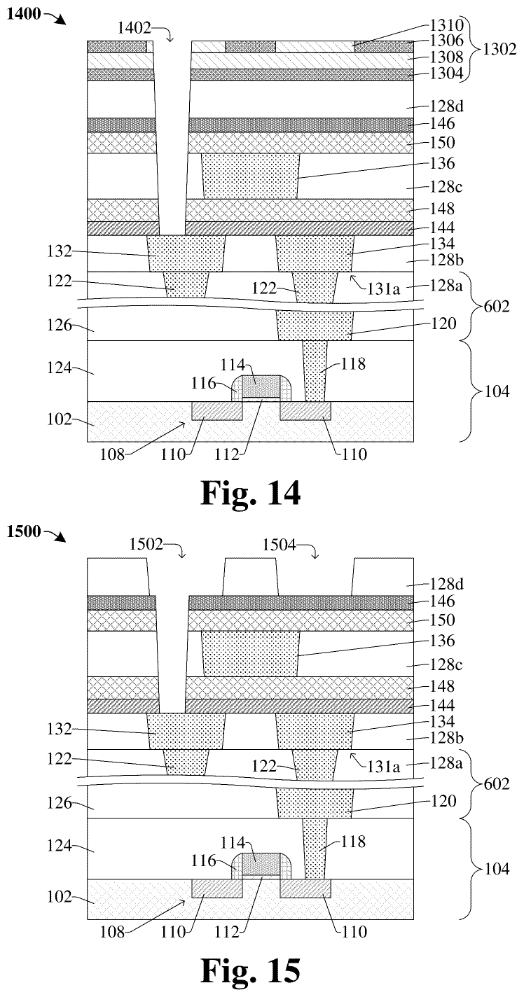

As shown in the cross-sectional view 1500 of FIG. 15, a second etching process is performed on the fourth dielectric layer 128d according to the masking structure (1302 of FIG. 14), thereby forming a first opening 1502 and a second opening 1504. The second etching process may, for example, include a dry etch process (e.g., a RIE process, a DRIE process, a plasma etch process, etc.), a wet etch process, some other suitable etch process, or any combination of the foregoing. Further, after the second etching process a removal process is performed to remove the masking structure (1302 of FIG. 14) from over the fourth dielectric layer 128d. The first opening 1502 includes portions of the via opening (1402 of FIG. 14) below the fourth dielectric layer 128d.

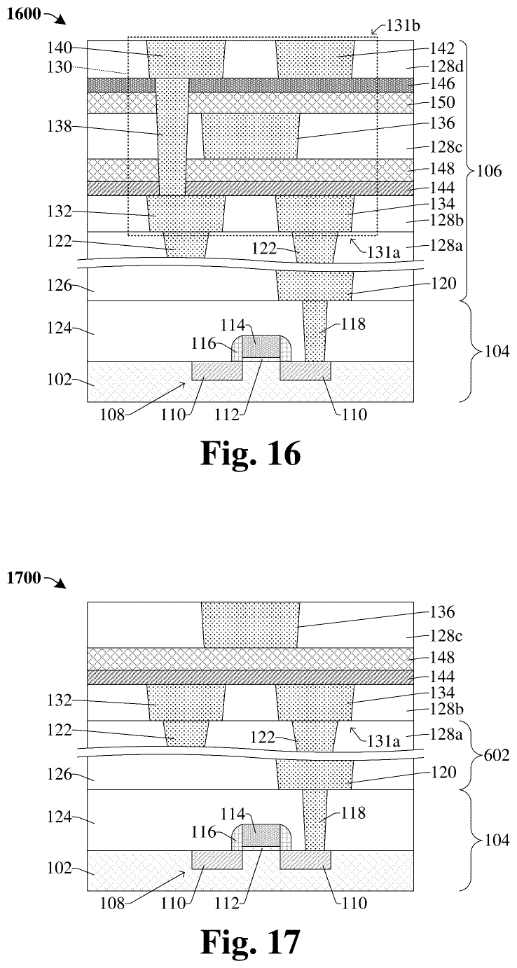

As shown in the cross-sectional view 1600 of FIG. 16, a conductive source/drain via 138 and a second pair of source/drain structures 140, 142 are formed in the first and second openings (1502, 1504 of FIG. 15), thereby forming an n-channel transistor 131b over the p-channel transistor 131a and defining or forming an electronic device 130 over the FEOL structure 104. The conductive source/drain via 138 and a first source/drain structure 140 in the second pair of source/drain structures 140, 142 are formed in the first opening (1502 of FIG. 15) and a second source/drain structure 142 in the second pair of source/drain structures 140, 142 is formed in the second opening (1504 of FIG. 15). In various embodiments, the lower BEOL structure (602 of FIG. 15) and the electronic device 130 are part of a BEOL structure 106. In some embodiments, a process for forming the conductive source/drain via 138 and the second pair of source/drain structures 140, 142 includes depositing (e.g., by CVD, PVD, ALD, etc.) one or more conductive materials in the first and second openings (1502, 1504 of FIG. 15) and performing a planarization process (e.g., a CMP process) on the one or more conductive materials. In various embodiments, depositing the one or more conductive materials includes depositing a conductive liner layer (e.g., comprising titanium nitride, tantalum nitride, etc.) lining the first and second openings (1502, 1504 of FIG. 15) and depositing a conductive core (e.g., copper, aluminum, tungsten, some other conductive material, or any combination of the foregoing) over the conductive liner layer. In various embodiments, a process for forming the n-channel transistor 131b includes the processing steps illustrated and/or described in FIGS. 10-16.

In various embodiments, forming the n-channel transistor 131b after the p-channel transistor 131a reduces a number of thermal annealing process the n-channel transistor 131b is exposed to. As a result, a diffusion of one or more elements from the second semiconductor layer 146 to adjacent dielectric material is mitigated. This increases a reliability and performance of the n-channel transistor 131b.

In some embodiments, additional levels of conductive vias and wires (not shown) may be formed over the electronic device 130. The additional levels of conductive vias and wires are part of the BEOL structure 106. Further, conductive vias and/or wires may be formed in the BEOL structure 106 concurrently with and at levels aligned with the first pair of source/drain structures 132, 134, the gate electrode 136, the conductive source/drain via 138, and the second pair of source/drain structures 140, 142. For example, a first level of conductive wires (not shown) may be formed the BEOL structure 106 in a region laterally offset from the first pair of source/drain structures 132, 134, where bottom surfaces of the first level of conductive wires are aligned with bottom surfaces of the source/drain structures in the first pair of source/drain structures 132, 134.

FIGS. 17-26 illustrate cross-sectional views 1700-2600 of some embodiments of a second method for forming an integrated chip (IC) having an electronic device that comprises transistors vertically stacked with one another according to the present disclosure. Although the cross-sectional views 1700-2600 shown in FIGS. 17-26 are described with reference to a second method, it will be appreciated that the structures shown in FIGS. 17-26 are not limited to the second method but rather may stand alone separate of the second method. Furthermore, although FIGS. 17-26 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 1700 of FIG. 17, a semiconductor substrate 102 is provided and a FEOL structure 104, a lower BEOL structure 602, and a p-channel transistor 131a are formed over the semiconductor substrate 102. In various embodiments, the structure of FIG. 17 is formed as illustrated and/or described in FIGS. 6-11.

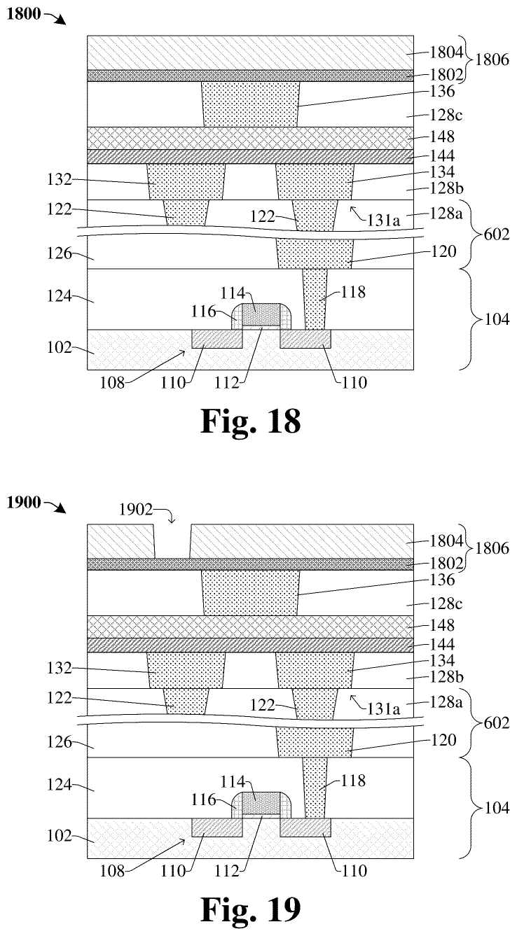

As shown in the cross-sectional view 1800 of FIG. 18, a first masking structure 1806 is formed on the gate electrode 136 and the third dielectric layer 128c. In some embodiments, the first masking structure 1806 includes a hard mask 1802 on the third dielectric layer 128c and a photoresist 1804 on the hard mask 1802. The hard mask 1802 may, for example, be formed by a CVD process, a PVD process, an ALD process, or some other suitable growth or deposition process. The photoresist 1804 may, for example, be formed by spin coating or some other suitable process. The hard mask 1802 may, for example, be or comprise titanium, titanium nitride, tungsten, some other metal, some other suitable material, or any combination of the foregoing.

As shown in the cross-sectional view 1900 of FIG. 19, an opening 1902 is formed in the photoresist 1804. In some embodiments, a process for forming the opening 1902 includes exposing (e.g., through ultraviolet (UV) light) the photoresist 1804 to a pattern of a photomask and immersing the photoresist 1804 in a developer solution.

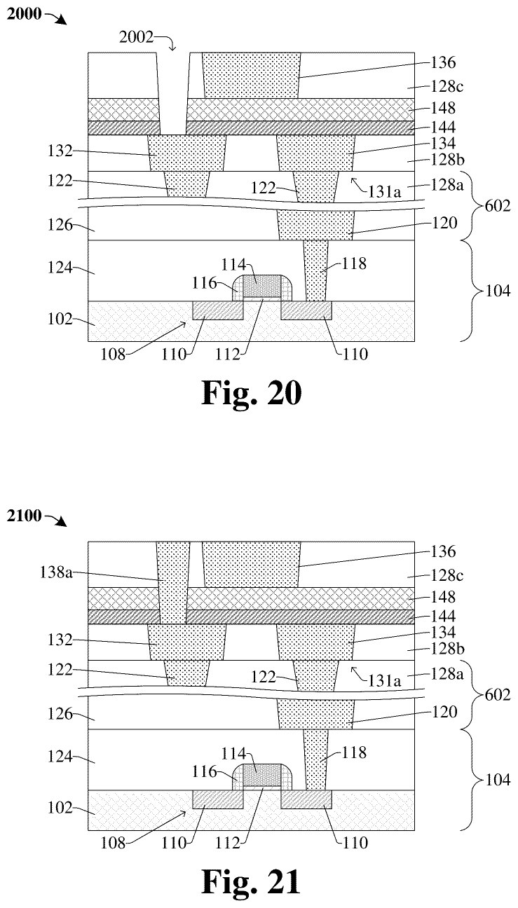

As shown in the cross-sectional view 2000 of FIG. 20, a first etching process is performed on the third dielectric layer 128c, the first gate dielectric layer 148, and the first semiconductor layer 144 to form an opening 2002 over an individual source/drain structure 132 in the first pair of source/drain structures 132, 134. In some embodiments, the first etching process includes exposing the third dielectric layer 128c, the first gate dielectric layer 148, and the first semiconductor layer 144 to one or more etchants with the first masking structure (1806 of FIG. 19) in place. The first etching process is, for example, an RIE process, a DRIE process, a plasma etch process, a wet etch process, some other suitable etch process, or any combination of the foregoing. After the first etching process a removal process is performed to remove the first masking structure (1806 of FIG. 19).

As shown in the cross-sectional view 2100 of FIG. 21, a lower via segment 138a is formed in the opening (2002 of FIG. 20). In some embodiments, a process for forming the lower via segment 138a includes depositing (e.g., by CVD, PVD, ALD, etc.) one or more conductive materials in the opening (2002 of FIG. 20) and performing a planarization process (e.g., a CMP process) on the one or more conductive materials.

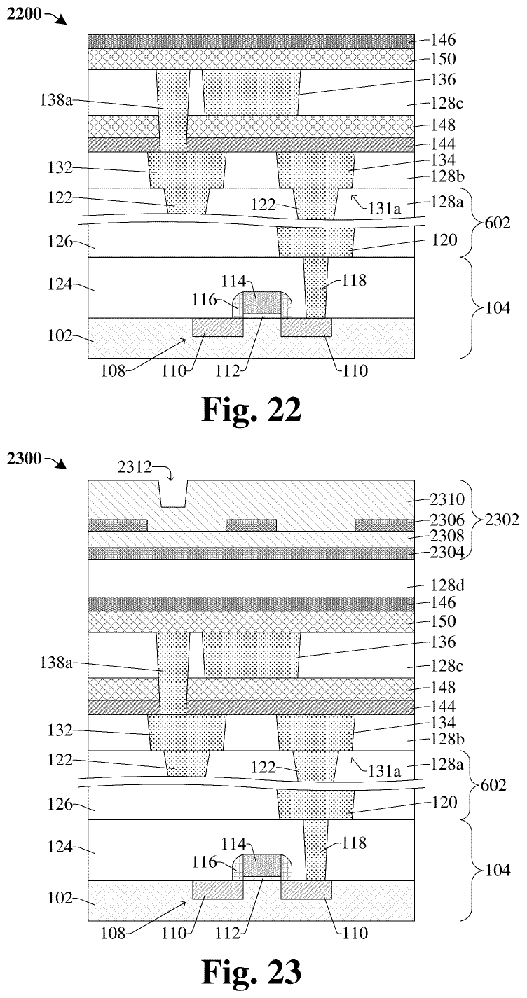

As shown in the cross-sectional view 2200 of FIG. 22, a second gate dielectric layer 150 is formed over the gate electrode 136 and the lower via segment 138a, and a second semiconductor layer 146 is formed on the second gate dielectric layer 150. In various embodiments, the second gate dielectric layer 150 and the second semiconductor layer 146 are formed as illustrated and/or described in FIG. 12.

As shown in the cross-sectional view 2300 of FIG. 23, a fourth dielectric layer 128d is formed over the second semiconductor layer 146 and a second masking structure 2302 is formed on the fourth dielectric layer 128d. In some embodiments, the second masking structure 2302 comprises a first hard mask 2304 on the fourth dielectric layer 128d, a first photoresist 2308 on the first hard mask 2304, a patterned hard mask 2306 over the first photoresist 2308, and a second photoresist 2310 over the patterned hard mask 2306. The second photoresist 2310 comprises sidewalls defining an opening over the lower via segment 138a. The fourth dielectric layer 128d may, for example, be formed by a CVD process, a PVD process, an ALD process, or some other suitable growth or deposition process. In some embodiments, the second masking structure 2302 may be formed by the processes described in regards to forming the masking structure 1302 of FIG. 13. In some embodiments, the first hard mask 2304 and the patterned hard mask 2306 may, for example, each be or comprise titanium, titanium nitride, tungsten, some other metal, some other suitable material, or any combination of the foregoing.

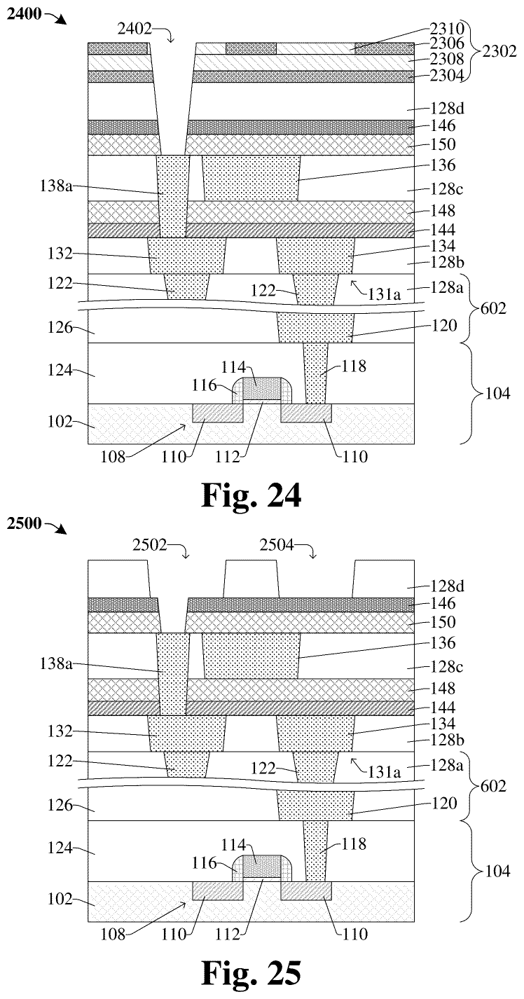

As shown in the cross-sectional view 2400 of FIG. 24, a second etching process is performed on the fourth dielectric layer 128d, the second semiconductor layer 146, and the second gate dielectric layer 150 according to the second masking structure 2302, thereby forming an opening 2402. The opening 2402 exposes an upper surface of the lower via segment 138a. The second etching process may, for example, include a dry etch process (e.g., a RIE process, a DRIE process, a plasma etch process, etc.), a wet etch process, some other suitable etch process, or any combination of the foregoing.

As shown in the cross-sectional view 2500 of FIG. 25, a third etching process is performed on the fourth dielectric layer 128d according to the second masking structure (2302 of FIG. 24), thereby forming a first opening 2502 and a second opening 2504. The third etching process may, for example, include a dry etch process (e.g., a RIE process, a DRIE process, a plasma etch process, etc.), a wet etch process, some other suitable etch process, or any combination of the foregoing. Further, after the third etching process a removal process is performed to remove the second masking structure (2302 of FIG. 24) from over the fourth dielectric layer 128d. The first opening 2502 includes portions of the opening (2402 of FIG. 24) below the fourth dielectric layer 128d.

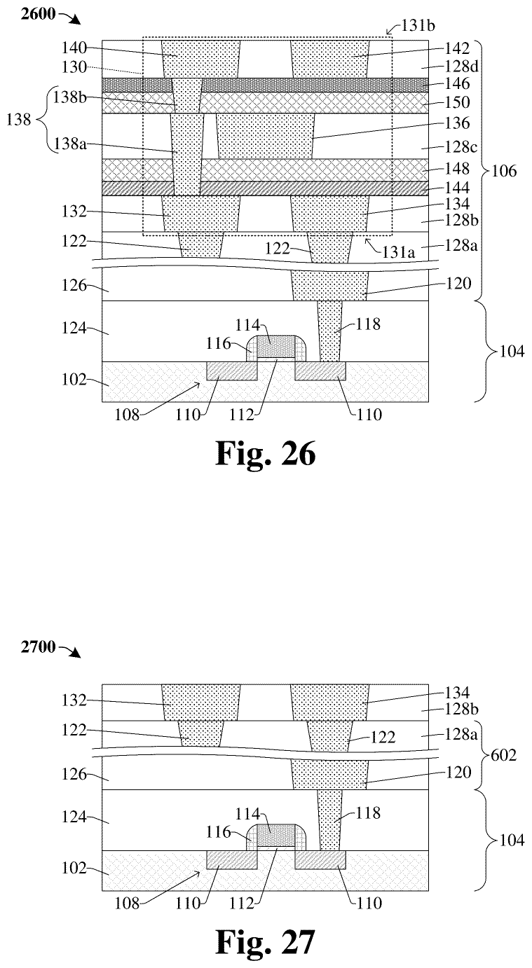

As shown in the cross-sectional view 2600 of FIG. 26, an upper via segment 138b and a second pair of source/drain structures 140, 142 are forming in the first and second openings (2502, 2504 of FIG. 25), thereby forming an n-channel transistor 131b over the p-channel transistor 131a and defining or forming an electronic device 130 over the FEOL structure 104. The upper via segment 138b and a first source/drain structure 140 in the second pair of source/drain structures 140, 142 are formed in the first opening (2502 of FIG. 25) and a second source/drain structure 142 in the second pair of source/drain structures 140, 142 is formed in the second opening (2504 of FIG. 25). In various embodiments, the lower BEOL structure (106 of FIG. 25) and the electronic device 130 are part of a BEOL structure 106. In some embodiments, a process for forming the upper via segment 138b and the second pair of source/drain structures 140, 142 includes depositing (e.g., by CVD, PVD, ALD, etc.) one or more conductive materials in the first and second openings (2502, 2504 of FIG. 25) and performing a planarization process (e.g., a CMP process) on the one or more conductive materials. In various embodiments, depositing the one or more conductive materials includes depositing a conductive liner layer (e.g., comprising titanium nitride, tantalum nitride, etc.) lining the first and second openings (2502, 2504 of FIG. 25) and depositing a conductive core (e.g., copper, aluminum, tungsten, some other conductive material, or any combination of the foregoing) over the conductive liner layer. In various embodiments, a process for forming the n-channel transistor 131b includes the processing steps illustrated and/or described in FIGS. 18-26. The lower via segment 138a and the upper via segment 138b define a conductive source/drain via 138.

FIGS. 27-38 illustrate cross-sectional views 2700-3800 of some embodiments of a third method for forming an integrated chip (IC) having an electronic device that comprises transistors vertically stacked with one another according to the present disclosure. Although the cross-sectional views 2700-3800 shown in FIGS. 27-38 are described with reference to a third method, it will be appreciated that the structures shown in FIGS. 27-38 are not limited to the third method but rather may stand alone separate of the third method. Furthermore, although FIGS. 27-38 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 2700 of FIG. 27, a semiconductor substrate 102 is provided an a FEOL structure 104, a lower BEOL structure 602, a second dielectric layer 128b, and a first pair of source/drain structures 132, 134 are formed over the semiconductor substrate 102. In some embodiments, the structure of FIG. 27 is formed as illustrated and/or described in FIGS. 6-8.

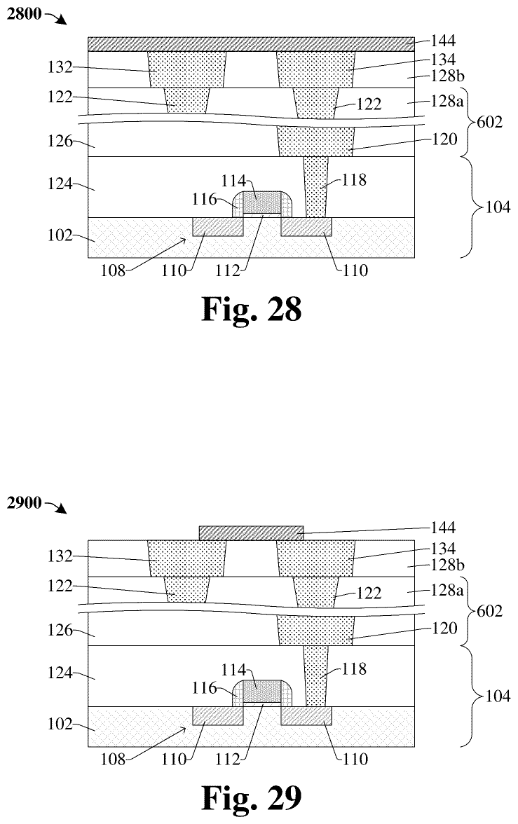

As shown in the cross-sectional view 2800 of FIG. 28, a first semiconductor layer 144 is formed on the first pair of source/drain structures 132, 134. The first semiconductor layer 144 may, for example, be formed by one or more deposition processes that may include one or more of a PVD process, a CVD process, an ALD process, or some other suitable growth or deposition process. Further, the one or more deposition processes is/are performed at a first deposition temperature that is, for example, less than or equal to about 400 degrees Celsius.

As shown in the cross-sectional view 2900 of FIG. 29, a patterning process is performed on the first semiconductor layer 144. The patterning process may, for example, include: forming a masking layer (not shown) over the first semiconductor layer 144; etching the first semiconductor layer 144 according to the masking layer; and removing the masking layer.

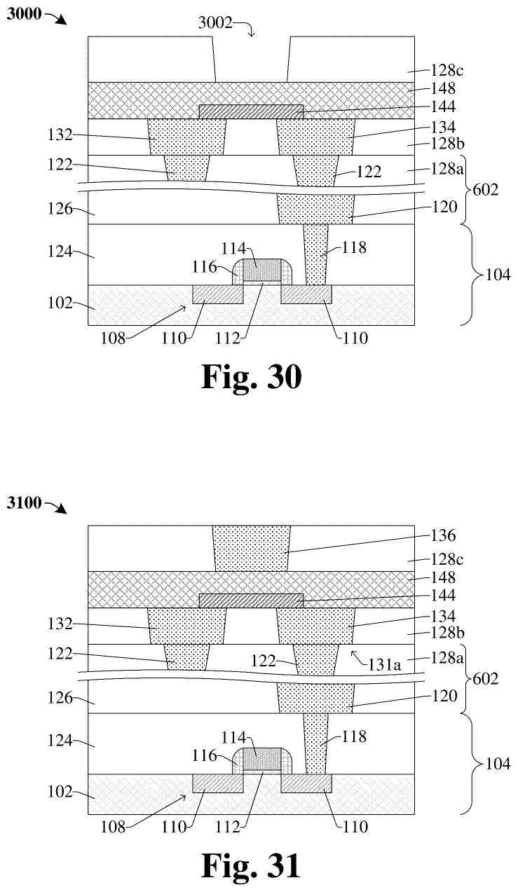

As shown in the cross-sectional view 3000 of FIG. 30, a first gate dielectric layer 148 is formed on the first semiconductor layer 144 and the first pair of source/drain structures 132, 134. The first gate dielectric layer 148 may, for example, be formed by a PVD process, a CVD process, an ALD process, or some other suitable growth or deposition process. In various embodiments, the first gate dielectric layer 148 directly contacts outer opposing sidewalls of the first semiconductor layer 144 and has a bottom surface aligned with a bottom surface of the first semiconductor layer 144.

Further, as shown in the cross-sectional view 3000, a third dielectric layer 128c is formed over the first gate dielectric layer 148 and an opening 3002 is formed in the third dielectric layer 128c. The third dielectric layer 128c may, for example, be formed by a CVD process, a PVD process, an ALD process, or some other suitable growth or deposition process. In some embodiments, a process for forming the opening 3002 includes: forming a masking layer (not shown) on the third dielectric layer 128c; etching the third dielectric layer 128c according to the masking layer; and performing a removal process to remove the masking layer.

As shown in the cross-sectional view 3100 of FIG. 31, a gate electrode 136 is formed in the third dielectric layer 128c, thereby forming a p-channel transistor 131a over the lower BEOL structure 602. The gate electrode 136 may be formed as illustrated and/or described in FIG. 11.

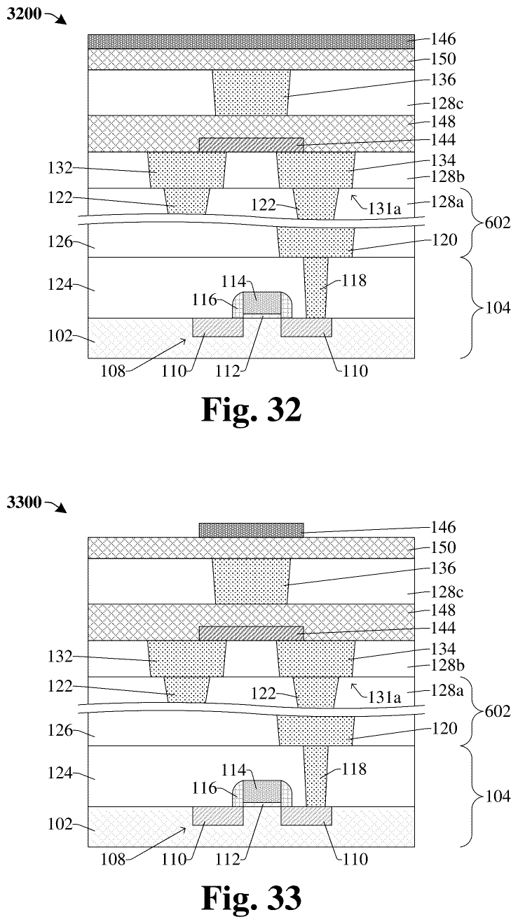

As shown in the cross-sectional view 3200 of FIG. 32, a second gate dielectric layer 150 is formed over the gate electrode 136 and a second semiconductor layer 146 is formed on the second gate dielectric layer 150. The second gate dielectric layer 150 and the second semiconductor layer 146 may be formed as illustrated and/or described in FIG. 12.

As shown in the cross-sectional view 3300 of FIG. 33, a patterning process is performed on the second semiconductor layer 146. The patterning process may, for example, include: forming a masking layer (not shown) over the second semiconductor layer 146; etching the second semiconductor layer 146 according to the masking layer; and removing the masking layer.

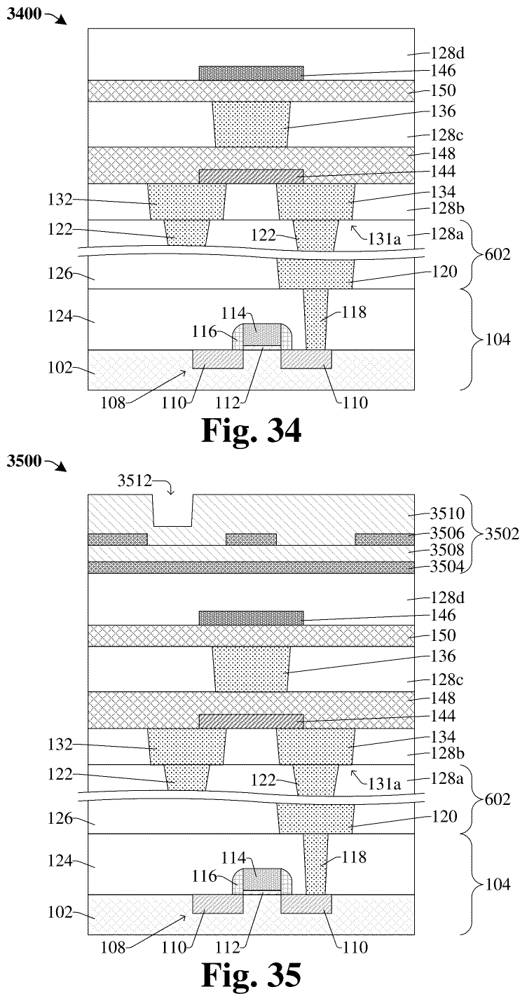

As shown in the cross-sectional view 3400 of FIG. 34, a fourth dielectric layer 128d is formed over the second semiconductor layer 146. The fourth dielectric layer 128d may, for example, be formed by a CVD process, a PVD process, an ALD process, or some other suitable growth or deposition process. In various embodiments, the fourth dielectric layer 128d directly contacts opposing outer sidewalls of the second semiconductor layer 146 and a bottom surface of the fourth dielectric layer 128d is aligned with a bottom surface of the second semiconductor layer 146.

As shown in the cross-sectional view 3500 of FIG. 35, a masking structure 3502 is formed on the fourth dielectric layer 128d. In some embodiments, the masking structure 3502 comprises a first hard mask 3504 on the fourth dielectric layer 128d, a first photoresist 3508 on the first hard mask 3504, a patterned hard mask 3506 over the first photoresist 3508, and a second photoresist 3510 over the patterned hard mask 3506. The second photoresist 3510 comprises sidewalls defining an opening 3512 over an individual source/drain structure 132 in the first pair of source/drain structures 132, 134. In some embodiments, the masking structure 3502 may be formed by the processes described in regards to forming the masking structure 1302 of FIG. 13. In some embodiments, the first hard mask 3504 and the patterned hard mask 3506 may, for example, each be or comprise titanium, titanium nitride, tungsten, some other metal, some other suitable material, or any combination of the foregoing.

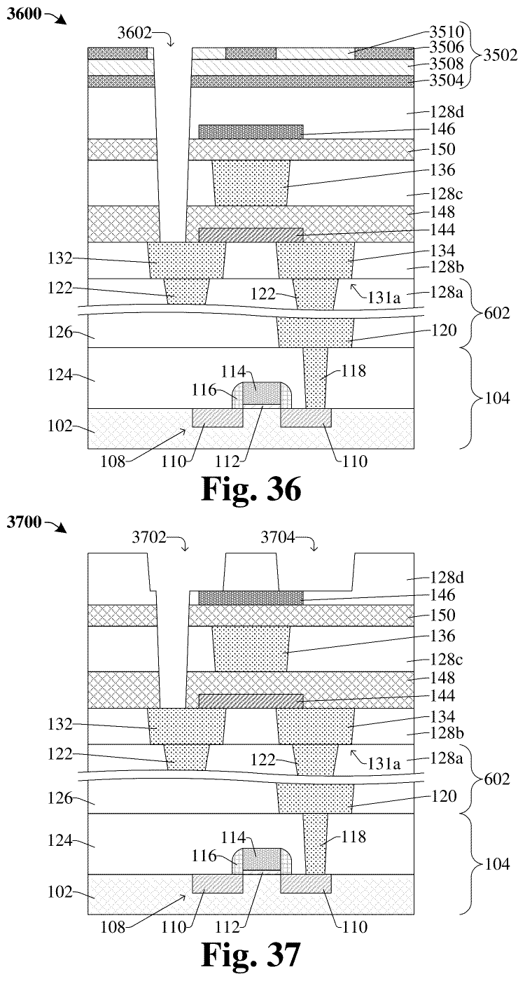

As shown in the cross-sectional view 3600 of FIG. 36, a first etching process is performed on the first gate dielectric layer 148, the third dielectric layer 128c, the second gate dielectric layer 150, and the fourth dielectric layer 128d according to the masking structure 3502, thereby forming a via opening 3602. The via opening 3602 exposes an upper surface of the individual source/drain structure 132 in the first pair of source/drain structures 132, 134. In some embodiments, the first etching process includes a dry etch process (e.g., a RIE process, a DRIE process, a plasma etch process, etc.), a wet etch process, some other suitable etch process, or any combination of the foregoing.

As shown in the cross-sectional view 3700 of FIG. 37, a second etching process is performed on the fourth dielectric layer 128d according to the masking structure (3502 of FIG. 36), thereby forming a first opening 3702 and a second opening 3704. The second etching process may, for example, include a dry etch process (e.g., a RIE process, a DRIE process, a plasma etch process, etc.), a wet etch process, some other suitable etch process, or any combination of the foregoing. Further, after the second etching process a removal process is performed to remove the masking structure (3502 of FIG. 36) from over the fourth dielectric layer 128d. The first opening 3702 includes portions of the via opening (3602 of FIG. 36) below the fourth dielectric layer 128d.

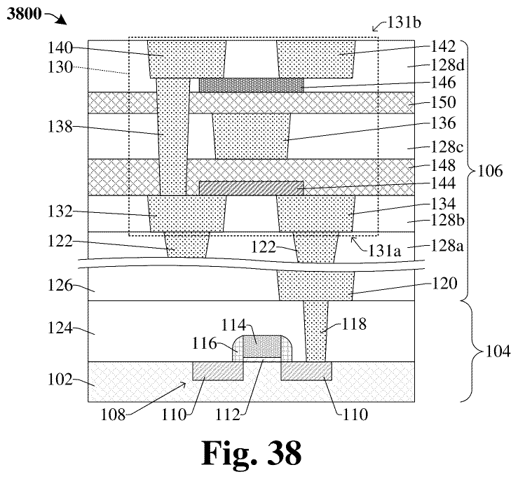

As shown in the cross-sectional view 3800 of FIG. 38, a conductive source/drain via 138 and a second pair of source/drain structures 140, 142 are formed in the first and second openings (3702, 3704 of FIG. 37), thereby forming an n-channel transistor 131b over the p-channel transistor 131a and defining or forming an electronic device 130 over the FEOL structure 104. The conductive source/drain via 138 and the second pair of source/drain structures 140, 142 may be formed as illustrated and/or described in FIG. 16.

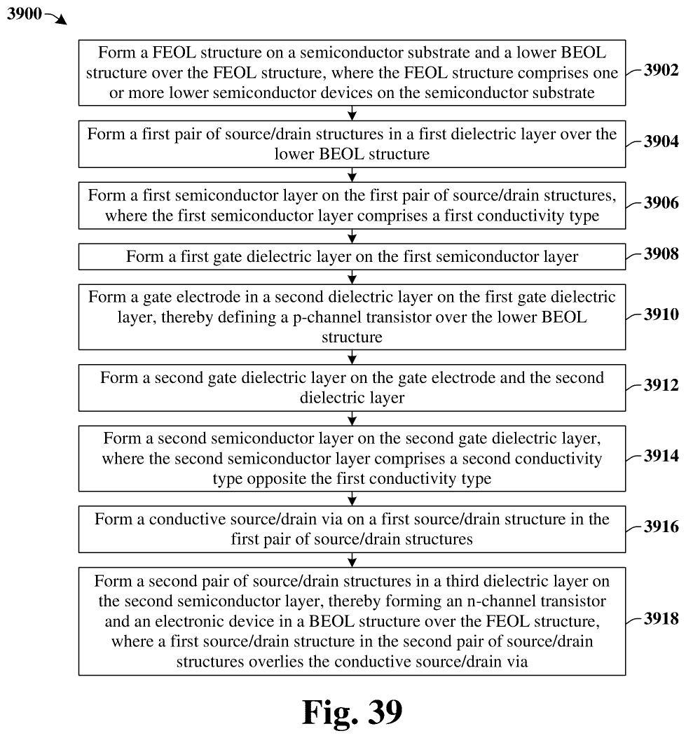

FIG. 39 illustrates a flow diagram of some embodiments of a method 3900 for forming an integrated chip (IC) having an electronic device that comprises transistors vertically stacked with one another according to the present disclosure. Although the method 3900 is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act 3902, a FEOL structure is formed on a semiconductor substrate and a lower BEOL structure is formed on the FEOL structure. The FEOL structure comprises one or more lower semiconductor devices on the semiconductor substrate. FIG. 6 illustrates cross-sectional view 600 corresponding to various embodiments of act 3902.

At act 3904, a first pair of source/drain structures is formed in a first dielectric layer over the lower BEOL structure. FIGS. 7 and 8 illustrate cross-sectional views 700 and 800 corresponding to various embodiments of act 3904.

At act 3906, a first semiconductor layer is formed on the first pair of source/drain structures, where the first semiconductor layer comprises a first conductivity type. FIG. 9 illustrates cross-sectional view 900 corresponding to various embodiments of act 3906. FIGS. 28 and 29 illustrate cross-sectional views 2800 and 2900 corresponding to some other embodiments of act 3906.

At act 3908, a first gate dielectric layer is formed on the first semiconductor layer. FIG. 9 illustrates cross-sectional view 900 corresponding to various embodiments of act 3908. FIG. 30 illustrates cross-sectional view 3000 corresponding to some other embodiments of act 3908.

At act 3910, a gate electrode is formed in a second dielectric layer on the first gate dielectric layer, thereby defining a p-channel transistor over the lower BEOL structure. FIGS. 10 and 11 illustrate cross-sectional views 1000 and 1100 corresponding to some embodiments of act 3910. FIGS. 30 and 31 illustrate cross-sectional views 3000 and 3100 corresponding to some other embodiments of act 3910.

At act 3912, a second gate dielectric layer is formed on the gate electrode and the second dielectric layer. FIG. 12 illustrates cross-sectional view 1200 corresponding to various embodiments of act 3912. FIG. 22 illustrates cross-sectional view 2200 corresponding to some other embodiments of act 3912. FIG. 32 illustrates cross-sectional view 3200 corresponding to further embodiments of act 3912.

At act 3914, a second semiconductor layer is formed on the second gate dielectric layer, where the second semiconductor layer comprises a second conductivity type opposite the first conductivity type. FIG. 12 illustrates cross-sectional view 1200 corresponding to various embodiments of act 3914. FIG. 22 illustrates cross-sectional view 2200 corresponding to some other embodiments of act 3914. FIGS. 32 and 33 illustrate cross-sectional views 3200 and 3300 corresponding to some other embodiments of act 3914.

At act 3916, a conductive source/drain via is formed on a first source/drain structure in the first pair of source/drain structures. FIGS. 13-16 illustrate cross-sectional views 1300-1600 corresponding to various embodiments of act 3916. FIGS. 18-21 and 23-26 illustrate cross-sectional views 1800-2100 and 2300-2600 corresponding to some other embodiments of act 3916. FIGS. 35-38 illustrate cross-sectional views 3500-3800 corresponding to further embodiments of act 3916.

At act 3918, a second pair of source/drain structures is formed in a third dielectric layer on the second semiconductor layer, thereby forming an n-channel transistor and an electronic device in a BEOL structure over the FEOL structure. A first source/drain structure in the second pair of source/drain structures overlies the conductive source/drain via. FIGS. 15 and 16 illustrate cross-sectional views 1500 and 1600 corresponding to various embodiments of act 3918. FIGS. 25 and 26 illustrate cross-sectional views 2500 and 2600 corresponding to some other embodiments of act 3918. FIGS. 37 and 38 illustrate cross-sectional views 3700 and 3800 corresponding to further embodiments of act 3918.

Accordingly, in some embodiments, the present application relates to an IC comprising an electronic device disposed in a BEOL structure over a semiconductor substrate, where the electronic device comprises an n-channel transistor overlying a p-channel transistor.

In some embodiments, the present application provides an integrated chip (IC), including: a lower dielectric structure overlying a semiconductor substrate; a gate structure over the lower dielectric structure, wherein the gate structure comprises a first surface opposite a second surface; a first semiconductor layer arranged between the first surface of the gate structure and the lower dielectric structure; and a second semiconductor layer over the second surface of the gate structure. In an embodiment, the IC further includes a plurality of conductive wires and a plurality of conductive vias disposed in the lower dielectric structure and underlying the first and second semiconductor layers. In an embodiment, the gate structure comprises a gate electrode, a first gate dielectric layer, and a second gate dielectric layer, wherein the first gate dielectric layer is arranged between the gate electrode and the first semiconductor layer, and wherein the second gate dielectric layer is arranged between the gate electrode and the second semiconductor layer. In an embodiment, the IC further includes: a first pair of source/drain structures arranged on the first semiconductor layer and spaced on opposing sides of the gate electrode; and a second pair of source/drain structures over the second semiconductor layer and spaced on the opposing sides of the gate electrode. In an embodiment, the IC further includes a conductive via vertically extending from a first source/drain structure in the first pair of source/drain structures to a first source/drain structure in the second pair of source/drain structures. In an embodiment, the conductive via directly contacts opposing sidewalls of the first semiconductor layer and opposing sidewalls of the second semiconductor layer. In an embodiment, outer sidewalls of the first semiconductor layer are spaced between the first pair of source/drain structures, wherein outer sidewalls of the second semiconductor layer are spaced between the second pair of source/drain structures. In an embodiment, the first semiconductor layer comprises a first material, the second semiconductor layer comprises a second material, and the semiconductor substrate comprises a third material, wherein the first material, the second material, and the third material are different from one another.

In some embodiments, the present application provides an integrated chip (IC), including: a lower interconnect structure over a semiconductor substrate; a first semiconductor device over the lower interconnect structure, wherein the first semiconductor device comprises a first pair of source/drain structures over the lower interconnect structure, a first semiconductor layer over the first pair of source/drain structures, and a first gate dielectric layer over the first semiconductor layer; a gate electrode over the first gate dielectric layer; and a second semiconductor device over the first semiconductor device, wherein the second semiconductor device comprises a second gate dielectric layer over the gate electrode, a second semiconductor layer over the second gate dielectric layer, and a second pair of source/drain structures over the second semiconductor layer. In an embodiment, the IC further includes a first dielectric layer disposed between the first and second gate dielectric layers, wherein the first dielectric layer laterally wraps around the gate electrode. In an embodiment, the first semiconductor device is configured as a p-channel transistor and the second semiconductor device is configured as an n-channel transistor. In an embodiment, outer sidewalls of the first semiconductor layer are spaced between the first pair of source/drain structures, wherein outer sidewalls of the second semiconductor layer are spaced between the second pair of source/drain structures. In an embodiment, the first gate dielectric layer directly contacts opposing sidewalls of the first semiconductor layer. In an embodiment, the first semiconductor layer comprises a first metal oxide and the second semiconductor layer comprises a second metal oxide different from the first metal oxide. In an embodiment, the IC further includes a transistor arranged on the semiconductor substrate, wherein the transistor comprises a pair of source/drain regions arranged in the semiconductor substrate and a lower gate electrode on the semiconductor substrate between the pair of source/drain regions, wherein an individual source/drain region in the pair of source/drain regions is electrically coupled to a first source/drain structure in the first pair of source/drain structures by way of the lower interconnect structure.

In some embodiments, the present application provides a method for forming an integrated chip (IC), the method including: forming a lower interconnect structure over a semiconductor substrate; forming a first pair of source/drain structures over the lower interconnect structure; depositing a first semiconductor layer over the first pair of source/drain structures; depositing a first gate dielectric layer over the first semiconductor layer; forming a gate electrode on the first gate dielectric layer; forming a second gate dielectric layer over the gate electrode; forming a second semiconductor layer over the second gate dielectric layer; and forming a second pair of source/drain structures over the second semiconductor layer. In an embodiment, the method further includes forming a conductive via between a first source/drain structure in the first pair of source/drain structures and a second source/drain structure in the second pair of source/drain structures. In an embodiment, the conductive via and the second source/drain structure are formed concurrently with one another. In an embodiment, forming the gate electrode includes: depositing a dielectric layer on the first gate dielectric layer; etching the dielectric layer to form an opening in the dielectric layer; depositing one or more conductive materials in the opening; and performing a planarization process on the one or more conductive materials. In an embodiment, depositing the one or more conductive materials comprises depositing a liner layer in the opening and depositing a conductive core over the liner layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip (IC), comprising:
a lower dielectric structure overlying a semiconductor substrate;
a gate structure over the lower dielectric structure, wherein the gate structure comprises a first surface opposite a second surface;
a first semiconductor layer arranged between the first surface of the gate structure and the lower dielectric structure; and
a second semiconductor layer over the second surface of the gate structure.

2. The IC of claim 1, further comprising:
a plurality of conductive wires and a plurality of conductive vias disposed in the lower dielectric structure and underlying the first and second semiconductor layers.

3. The IC of claim 1, wherein the gate structure comprises a gate electrode, a first gate dielectric layer, and a second gate dielectric layer, wherein the first gate dielectric layer is arranged between the gate electrode and the first semiconductor layer, and wherein the second gate dielectric layer is arranged between the gate electrode and the second semiconductor layer.

4. The IC of claim 3, further comprising:
a first pair of source/drain structures arranged on the first semiconductor layer and spaced on opposing sides of the gate electrode; and
a second pair of source/drain structures over the second semiconductor layer and spaced on the opposing sides of the gate electrode.

5. The IC of claim 4, further comprising:
a conductive via vertically extending from a first source/drain structure in the first pair of source/drain structures to a first source/drain structure in the second pair of source/drain structures.

6. The IC of claim 5, wherein the conductive via directly contacts opposing sidewalls of the first semiconductor layer and opposing sidewalls of the second semiconductor layer.

7. The IC of claim 4, wherein outer sidewalls of the first semiconductor layer are spaced between the first pair of source/drain structures, wherein outer sidewalls of the second semiconductor layer are spaced between the second pair of source/drain structures.

8. The IC of claim 1, wherein the first semiconductor layer comprises a first material, the second semiconductor layer comprises a second material, and the semiconductor substrate comprises a third material, wherein the first material, the second material, and the third material are different from one another.

9. An integrated chip (IC), comprising:
a lower interconnect structure over a semiconductor substrate;
a first semiconductor device over the lower interconnect structure, wherein the first semiconductor device comprises a first pair of source/drain structures over the lower interconnect structure, a first semiconductor layer over the first pair of source/drain structures, and a first gate dielectric layer over the first semiconductor layer;
a gate electrode over the first gate dielectric layer; and
a second semiconductor device over the first semiconductor device, wherein the second semiconductor device comprises a second gate dielectric layer over the gate electrode, a second semiconductor layer over the second gate dielectric layer, and a second pair of source/drain structures over the second semiconductor layer.

10. The IC of claim 9, further comprising:
a first dielectric layer disposed between the first and second gate dielectric layers, wherein the first dielectric layer laterally wraps around the gate electrode.

11. The IC of claim 9, wherein the first semiconductor device is configured as a p-channel transistor and the second semiconductor device is configured as an n-channel transistor.

12. The IC of claim 9, wherein outer sidewalls of the first semiconductor layer are spaced between the first pair of source/drain structures, wherein outer sidewalls of the second semiconductor layer are spaced between the second pair of source/drain structures.

13. The IC of claim 12, wherein the first gate dielectric layer directly contacts opposing sidewalls of the first semiconductor layer.

14. The IC of claim 9, wherein the first semiconductor layer comprises a first metal oxide and the second semiconductor layer comprises a second metal oxide different from the first metal oxide.

15. The IC of claim 9, further comprising:
a transistor arranged on the semiconductor substrate, wherein the transistor comprises a pair of source/drain regions arranged in the semiconductor substrate and a lower gate electrode on the semiconductor substrate between the pair of source/drain regions, wherein an individual source/drain region in the pair of source/drain regions is electrically coupled to a first source/drain structure in the first pair of source/drain structures by way of the lower interconnect structure.

16. A method for forming an integrated chip (IC), comprising:
forming a lower interconnect structure over a semiconductor substrate;
forming a first pair of source/drain structures over the lower interconnect structure;
depositing a first semiconductor layer over the first pair of source/drain structures;
depositing a first gate dielectric layer over the first semiconductor layer;
forming a gate electrode on the first gate dielectric layer;
forming a second gate dielectric layer over the gate electrode;
forming a second semiconductor layer over the second gate dielectric layer; and
forming a second pair of source/drain structures over the second semiconductor layer.

17. The method of claim 16, further comprising:
forming a conductive via between a first source/drain structure in the first pair of source/drain structures and a second source/drain structure in the second pair of source/drain structures.

18. The method of claim 17, wherein the conductive via and the second source/drain structure are formed concurrently with one another.

19. The method of claim 17, wherein forming the gate electrode comprises:
depositing a dielectric layer on the first gate dielectric layer;
etching the dielectric layer to form an opening in the dielectric layer;
depositing one or more conductive materials in the opening; and
performing a planarization process on the one or more conductive materials.

20. The method of claim 19, wherein depositing the one or more conductive materials comprises depositing a liner layer in the opening and depositing a conductive core over the liner layer.
